(19) United States
(12) Patent Application Publication
(10) Pub. No.: US 2011/0104862 A1
(43) Pub. Date: May 5, 2011

(54) METHOD OF FORMING SEMICONDUCTOR DEVICE AND SEMICONDUCTOR DEVICE

(75) Inventor: Tomohiro KADOYA, Tokyo (JP)

(73) Assignee: ELPIDA MEMORY, INC., Tokyo (JP)

(21) Appl. No.: 12/917,731

(22) Filed: Nov. 2, 2010

(30) Foreign Application Priority Data
Nov. 5, 2009 (JP) 2009-253985

(51) Int. Cl. H01L 21/336; H01L 21/28

(52) U.S. Cl. 438/270; 438/589; 257/E21.41; 257/E21.19

(57) ABSTRACT

A method of forming a semiconductor device includes the following processes. A first semiconductor structure is formed, which extends upwardly in a direction perpendicular to a main surface from a surface of a semiconductor substrate. A first insulating film is formed which extends on a surface of the first semiconductor structure. A gate electrode is formed which extends on the first insulating film. The gate electrode has a top surface which is lower than a top surface of the first semiconductor structure. A liner film is formed, which may include, but is not limited to, first and second liner portions. The first liner portion covers the gate electrode. The second liner portion extends upwardly from the top surface of the gate electrode. The liner film includes nitrogen and oxygen.

### BACKGROUND OF THE INVENTION

1. Field of the Invention

The present invention relates to a method of forming a semiconductor device and a semiconductor device.

Priority is claimed on Japanese Patent Application No. 2009-253985, filed Nov. 5, 2009, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

The degree of integration of a semiconductor device has been improved mainly by scaling down transistors. Reduced dimensions of transistors are now close to these limits. Further reduction in the dimensions of transistors beyond the limits will cause short channel effects which prevent normal operations of transistors.

Accordingly, technologies that form a predetermined circuit using vertical MOS transistors haves been developed. These technologies are disclosed in Japanese Unexamined Patent Application Publications Nos. 2009-164597 and 2007-048941. These technologies will make it possible to reduce area occupied over as well as to suppress the short channel effects.

There has been known a method of manufacturing a high-integration semiconductor device through construction for a memory cell array of DRAM devices or the like using vertical type MOS transistors.

Such a vertical MOS transistor is formed by forming a channel region (body region) through patterning of a semiconductor substrate in a pillar shape (columnar shape) using a predetermined mask and then arranging a gate electrode on a side surface of the channel region.

There is a method of forming an interlayer insulating film in the case where vertical MOS transistors are arranged at high density such as a memory cell array. There has been known a method of accumulating a silicon oxide (SiO₂) film using a typical CVD method. According to this method, it is insufficient to fill up, with an insulator, a gap between adjacent pillars, and thus forming cavities (voids) in the insulator between the adjacent pillars.

Accordingly, it is preferable to use a coated insulation film (hereinafter referred to as “spin on dielectrics (SOD) film”) such as polysilazane as the interlayer insulating film for filling a gap between the pillars of the vertical MOS transistors. The SOD film such as polysilazane can be converted (modified) into a solid body having a dense film quality by performing heat treatment to the SOD film under high-temperature oxidation atmosphere after coating. Accordingly, the formation of cavities (voids) can be prevented.

As the related art using a SOD film as an interlayer insulating film, there has been known a method of providing grooves on a semiconductor substrate and providing an insulating film having anti-oxidation properties in the grooves as a liner film. By coating the SOD film on the liner film, a shallow trench isolation (STI) is formed which has a structure filled with the SOD film via the liner film.

By forming the liner film as described above, the influence of oxidation to the base layer can be prevented and it becomes possible to perform heat treatment to the SOD film in an oxidation atmosphere. Accordingly, the film density of the SOD film can be increased. The life time of a memory cell portion can be increased. These technologies are disclosed in Japanese Unexamined Patent Application Publication No. 2001-010366.

Since the lower portion of the pillar is a part of the semiconductor substrate, in order to form bit lines thereon, it is necessary to embed the bit lines in the substrate. These technologies are disclosed in Japanese Unexamined Patent Application Publication No. 2009-010366.

### SUMMARY

In one embodiment, a method of forming a semiconductor device may include, but is not limited to, the following processes. A first semiconductor structure is formed, which extends upwardly in a direction perpendicular to a main surface from a surface of a semiconductor substrate. A first insulating film is formed which extends on a surface of the first semiconductor structure. A gate electrode is formed which extends on the first insulating film. The gate electrode has a top surface which is lower than a top surface of the first semiconductor structure. A liner film is formed, which may include, but is not limited to, first and second liner portions. The first liner portion covers the gate electrode. The second liner portion extends upwardly from the top surface of the gate electrode. The liner film includes nitrogen and oxygen.

In another embodiment, a method of forming a semiconductor device may include, but is not limited to, the following processes. A nitride mask is formed over a semiconductor substrate. The semiconductor substrate is selectively etched to form semiconductor pillars and grooves that define the semiconductor pillars. The semiconductor pillars extend upwardly from the semiconductor substrate. Gate insulating films are formed which cover the grooves, while the nitride mask remaining over the pillars. Gate electrodes are formed on the gate insulating films, while the nitride mask remains over the pillars. The gate electrodes are lower in top level than the semiconductor pillars. The gate electrode faces toward the semiconductor pillar through the gate insulating film. Liner films of silicon oxynitride are formed, which cover the grooves. Spin-on-dielectrics-interlayer insulating films are formed, which cover the liner films and fill the grooves. A heat treatment of the spin-on-dielectrics-interlayer insulating films is performed in an oxidation atmosphere to increase a film density of the spin-on-dielectrics-interlayer insulating film. The nitride mask is selectively removed.

In still another embodiment, a method of forming a semiconductor device may include, but is not limited to, the following processes. Semiconductor pillars and grooves are formed using a mask. The pillars are defined by the grooves. The pillars extend upwardly from a surface of a semiconductor substrate. Gate electrodes are formed which extend surrounding the semiconductor pillars. The gate electrode is lower in top level than the semiconductor pillar. Liner films are formed, which cover the gate electrodes. The liner film extends upwardly from the top of the gate electrode. The liner film extends along an upper portion of the side surface of the semiconductor pillar. The upper portion of the side surface is positioned over the top of the gate electrode. A first inter-layer insulating film is formed, which covers the liner film. A heat treatment is performed in an oxidation atmosphere to increase a film density of the first inter-layer insulating film. The mask is selectively removed. Contact plugs are formed over the semiconductor pillars and the liner films, while the liner films being present over the gate electrodes and separating the semiconductor pillars from the contact plugs.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a semiconductor substrate in a step involved in a method of forming a semiconductor device in accordance with a first embodiment of the present invention;

FIG. 2A is a fragmentary cross sectional elevation view illustrating a semiconductor substrate in a step, subsequent to the step of FIG. 1, involved in the method of forming the semiconductor device in accordance with the first embodiment of the present invention;

FIG. 2B is a fragmentary plan view illustrating the semiconductor substrate with a 2X-2X′ line, taken along which FIG. 2A is illustrated;

FIG. 3 is a fragmentary cross sectional elevation view illustrating a semiconductor substrate in a step, subsequent to the step of FIG. 2A, involved in the method of forming the semiconductor device in accordance with the first embodiment of the present invention;

FIG. 4A is a fragmentary cross sectional elevation view illustrating a semiconductor substrate in a step, subsequent to the step of FIG. 3, involved in the method of forming the semiconductor device in accordance with the first embodiment of the present invention;

FIG. 4B is a fragmentary plan view illustrating the semiconductor substrate with a 4X-4X′ line, taken along which FIG. 4A is illustrated;

FIG. 5 is a fragmentary cross sectional elevation view illustrating a semiconductor substrate in a step, subsequent to the step of FIG. 4A, involved in the method of forming the semiconductor device in accordance with the first embodiment of the present invention;

FIG. 6 is a fragmentary cross sectional elevation view illustrating a semiconductor substrate in a step, subsequent to the step of FIG. 5, involved in the method of forming the semiconductor device in accordance with the first embodiment of the present invention;

FIG. 7 is a fragmentary cross sectional elevation view illustrating a semiconductor substrate in a step, subsequent to the step of FIG. 6, involved in the method of forming the semiconductor device in accordance with the first embodiment of the present invention;

FIG. 8A is a fragmentary cross sectional elevation view illustrating a semiconductor substrate in a step, subsequent to the step of FIG. 7, involved in the method of forming the semiconductor device in accordance with the first embodiment of the present invention;

FIG. 8B is a fragmentary enlarged cross sectional elevation view illustrating the semiconductor substrate of FIG. 8A;

FIG. 9 is a fragmentary cross sectional elevation view illustrating a semiconductor substrate in a step, subsequent to the step of FIG. 8A, involved in the method of forming the semiconductor device in accordance with the first embodiment of the present invention;

FIG. 10 is a fragmentary cross sectional elevation view illustrating a semiconductor substrate in a step, subsequent to the step of FIG. 9, involved in the method of forming the semiconductor device in accordance with the first embodiment of the present invention;

FIG. 11 is a fragmentary cross sectional elevation view illustrating a semiconductor substrate in a step, subsequent to the step of FIG. 10, involved in the method of forming the semiconductor device in accordance with the first embodiment of the present invention;

FIG. 12A is a fragmentary cross sectional elevation view illustrating a semiconductor substrate in a step involved in a method of forming a semiconductor device in accordance with a second embodiment of the present invention;

FIG. 12B is a fragmentary plan view illustrating the semiconductor substrate with a 12X-12X′ line, taken along which FIG. 12A is illustrated;

FIG. 13 is a fragmentary cross sectional elevation view illustrating a semiconductor substrate in a step, subsequent to the step of FIG. 12A, involved in the method of forming the semiconductor device in accordance with the second embodiment of the present invention;

FIG. 14 is a fragmentary cross sectional elevation view illustrating a semiconductor substrate in a step, subsequent to the step of FIG. 13, involved in the method of forming the semiconductor device in accordance with the second embodiment of the present invention;

FIG. 15A is a fragmentary cross sectional elevation view illustrating a semiconductor substrate in a step, subsequent to the step of FIG. 14, involved in a method of forming a semiconductor device in accordance with the second embodiment of the present invention;

FIG. 15B is a fragmentary plan view illustrating the semiconductor substrate with a 15X-15X′ line, taken along which FIG. 15A is illustrated;

FIG. 16A is a fragmentary cross sectional elevation view illustrating a semiconductor substrate in a step, subsequent to the step of FIG. 15A, involved in a method of forming a semiconductor device in accordance with the second embodiment of the present invention;

FIG. 16B is a fragmentary cross sectional elevation view illustrating a semiconductor substrate in the same step as illustrated in FIG. 16A, subsequent to the step of FIG. 15A, involved in a method of forming a semiconductor device in accordance with the second embodiment of the present invention;

FIG. 16C is a fragmentary plan view illustrating the semiconductor substrate with a 16X1-16X1′ line, taken along which FIG. 16A is illustrated and with a 16X2-16X2′ line, taken along which FIG. 16B is illustrated;

FIG. 17A is a fragmentary cross sectional elevation view illustrating a semiconductor substrate in a step, subsequent to the step of FIG. 16A, involved in a method of forming a semiconductor device in accordance with the second embodiment of the present invention;

FIG. 17B is a fragmentary cross sectional elevation view illustrating a semiconductor substrate in the same step as illustrated in FIG. 17A, subsequent to the step of FIG. 16A, involved in a method of forming a semiconductor device in accordance with the second embodiment of the present invention;

FIG. 17C is a fragmentary plan view illustrating the semiconductor substrate with a 17X1-17X1′ line, taken along which FIG. 17A is illustrated and with a 17X2-17X2′ line, taken along which FIG. 17B is illustrated;

FIG. 18A is a fragmentary cross sectional elevation view illustrating a semiconductor substrate in a step, subsequent to the step of FIG. 17A, involved in a method of forming a semiconductor device in accordance with the second embodiment of the present invention;

FIG. 18B is a fragmentary cross sectional elevation view illustrating a semiconductor substrate in a step, subsequent to the step of FIG. 18A, involved in a method of forming a semiconductor device in accordance with the second embodiment of the present invention;

FIG. 19A is a fragmentary cross sectional elevation view illustrating a semiconductor substrate in a step, subsequent to the step of FIG. 18B, involved in a method of forming a semiconductor device in accordance with the second embodiment of the present invention;

FIG. 19B is a fragmentary cross sectional elevation view illustrating a semiconductor substrate in a step, subsequent to the step of FIG. 19A, involved in a method of forming a semiconductor device in accordance with the second embodiment of the present invention;

FIG. 20A is a fragmentary cross sectional elevation view illustrating a semiconductor substrate in a step, subsequent to the step of FIG. 19B, involved in a method of forming a semiconductor device in accordance with the second embodiment of the present invention;

FIG. 20B is a fragmentary cross sectional elevation view illustrating a semiconductor substrate in a step, subsequent to the step of FIG. 20A, involved in a method of forming a semiconductor device in accordance with the second embodiment of the present invention;

FIG. 21 is a fragmentary cross sectional elevation view illustrating a semiconductor substrate in a step, subsequent to the step of FIG. 20B, involved in a method of forming a semiconductor device in accordance with the second embodiment of the present invention;

FIG. 22A is a fragmentary cross sectional elevation view illustrating a semiconductor substrate in a step, subsequent to the step of FIG. 21, involved in a method of forming a semiconductor device in accordance with the second embodiment of the present invention;

FIG. 22B is a fragmentary cross sectional elevation view illustrating a semiconductor substrate in the same step as illustrated in FIG. 22A, subsequent to the step of FIG. 21, involved in a method of forming a semiconductor device in accordance with the second embodiment of the present invention;

FIG. 22C is a fragmentary cross sectional elevation view illustrating a semiconductor substrate in the same step as illustrated in FIG. 22A, subsequent to the step of FIG. 21, involved in a method of forming a semiconductor device in accordance with the second embodiment of the present invention;

FIG. 22D is a fragmentary plan view illustrating the semiconductor substrate with a 22X1-22X1′ line, taken along which FIG. 22A is illustrated, with a 22X2-22X2′ line, taken along which FIG. 22B is illustrated and with a 22Y1-22Y1′ line, taken along which FIG. 22C is illustrated;

FIG. 23A is a fragmentary cross sectional elevation view illustrating a semiconductor substrate in a step, subsequent to the step of FIG. 22A, involved in a method of forming a semiconductor device in accordance with the second embodiment of the present invention; and

FIG. 23B is a fragmentary cross sectional elevation view illustrating a semiconductor substrate in the same step as illustrated in FIG. 23A, subsequent to the step of FIG. 22C, involved in a method of forming a semiconductor device in accordance with the second embodiment of the present invention.

### DETAILED DESCRIPTION OF THE PREFERRED EMBODIMENTS

Before describing the present invention, the related art will be explained in detail, in order to facilitate the understanding of the present invention.

There has been caused the following problem in the process of forming a liner film between pillars of vertical MOS transistors and embedding the liner film in an interlayer insulating film composed of an SOD film.

First, a semiconductor substrate is patterned in a predetermined shape using a hard mask, and thus pillars for vertical MOS transistors are formed. At this time, it is preferable that the hard mask is formed of a silicon nitride film having anti-oxidation properties since the hard mask is exposed to an oxidation atmosphere in the process of forming an interlayer insulating film to be described later.

Then, a gate electrode is formed on a side surface portion of the pillar in a state where the hard mask remains. Then, by sequentially laminating a liner film and a SOD film, the interlayer insulating film is formed. At this time, since it is necessary that the liner film is an insulating film having anti-oxidation properties, a silicon nitride (Si₃N₄) film, which is used in the related art, is used as a material of the liner film.

Then, the film density of the SOD film is increased by performing heat treatment to the SOD film under the oxidation atmosphere, and then the hard mask on the upper surface of the pillars is removed.

At this time, since it is necessary to remove the hard mask without damaging the pillars, the hard mask is selectively removed using wet etching. At this time, the SOD film is not removed by the wet etching.

Since the liner film is made of a silicon nitride film in the same manner as the hard mask, a chemical fluid permeates into a portion where the liner film is exposed. Accordingly, the liner film on the side surface of the pillar is removed simultaneously with the hard mask, and a gap occurs between the side surface of the pillar and the SOD film. Accordingly, if it is intended to completely remove the hard mask, the liner film between them is also removed to expose a portion of the gate electrode surface.

Also, in order to remove the hard mask, it is necessary to perform over-etching in addition to the etching of up to the depth of the hard mask in consideration of the difference in film thickness of the hard mask in the manufacturing process. Due to this, the remaining portion of the liner film is lost, and a gap that reaches a portion of the upper surface of the gate electrode may be formed.

Thereafter, if an electrode formed such that the electrode is in contact with the upper surface of the pillar is at this time, an electrode material penetrates the gap between the side surface of the pillar and the SOD film. Due to this, a short circuit is formed between the gate electrode and an electrode or a contact plug that is in contact with the upper surface of the pillar with the electrode material.

If it is intended to form the interlayer insulating film using the liner film composed of the silicon nitride film at the time of manufacturing the semiconductor device composed of vertical MOS transistors as described above, in the method of manufacturing in the related art, normal operation of the transistor is inhibited, and thus this causes the manufacturing yield of the semiconductor device to deteriorate.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device may include, but is not limited to, the following processes. A first semiconductor structure is formed, which extends upwardly in a direction perpendicular to a main surface from a surface of a semiconductor substrate. A first insulating film is formed which extends on a surface of the first semiconductor structure. A gate electrode is formed which extends on the first insulating film. The gate electrode has a top surface which is lower than a top surface of the first semiconductor structure. A liner film is formed, which may include, but is not limited to, first and second liner portions. The first liner portion covers the gate electrode. The second liner portion extends upwardly from the top surface of the gate electrode. The liner film includes nitrogen and oxygen.

In some cases, the method may further include, but is not limited to, forming a contact plug over the first semiconductor structure and the second liner portion, while the second liner portion being present over the gate electrode and separating the first semiconductor structure from the contact plug.

In some cases, the method may further include, but is not limited to, forming a first inter-layer insulating film which covers the liner film before forming the contact plug.

In some cases, the method may further include, but is not limited to, performing a heat treatment in an oxidation atmosphere, after forming the first inter-layer insulating film and before forming the contact plug.

In some cases, the method may further include, but is not limited to, forming a first mask pattern over the semiconductor substrate. Forming the first semiconductor structure may include, but is not limited to, selectively removing the semiconductor substrate using the first mask pattern. The first mask pattern is removed after performing the heat treatment and before forming the contact plug over the first semiconductor structure.

In some cases, the method may further include, but is not limited to, forming a first diffusion region in an upper portion of the first semiconductor structure after removing the first mask pattern and before forming the contact plug on the first diffusion region.

In some cases, forming the first semiconductor structure may include, but is not limited to, forming at least two of grooves on the main surface of the semiconductor substrate to form a semiconductor fin structure; and removing a part of the fin structure to form a pillar structure of the semiconductor substrate.

In some cases, forming the first inter-layer insulating film may include, but is not limited to, filling the grooves with the first inter-layer insulating film.

In some cases, the method may further include, but is not limited to, forming a second diffusion region beneath the surface of the semiconductor substrate. Forming the first semiconductor structure may include, but is not limited to, forming a plurality of first semiconductor pillars, each of which is surrounded by first grooves. Each of the first groove has a bottom surface beneath which the second diffusion region is formed. Forming the gate electrode may include, but is not limited to, forming a plurality of gate electrodes, each of which surrounds the first semiconductor pillar.

In some cases, forming the first semiconductor structure may include, but is not limited to, the following processes. A plurality of semiconductor fins is formed, each of which is defined by second grooves. The plurality of semiconductor fins and the second groves extend in a first horizontal direction. Bit lines are formed over the surface of the semiconductor substrate after forming the first semiconductor structure. The bit line extends over a bottom surface of the second groove. A part of the bit line contacts directly a part of a side surface of the semiconductor fin. An impurity is diffused from the bit line into the semiconductor fin to form a third diffusion region in the second fin. Third grooves are formed in the semiconductor substrate. The third grooves extend in a second horizontal direction different from the first horizontal direction. The third grooves separate the semiconductor fins into semiconductor pillars. The third groove has a bottom level which is higher than a center level of the third diffusion region.

In some cases, forming the gate electrode may include, but is not limited to, the following processes. A plurality of gate electrodes is formed, each of which extends in the second horizontal direction. The gate electrode faces toward the semiconductor pillar through the gate insulating film. Forming the first inter-layer insulating film may include, but is not limited to, forming the first inter-layer insulating film which fills the third grooves after forming the liner film.

In some cases, forming the bit lines may include, but is not limited to, the following processes. Openings are formed in the gate insulating films in the second grooves. The opening extends in the first horizontal direction. The opening exposes the part of the side surface of the semiconductor fin. The second grooves are filled with the bit lines so that the bit lines contact directly the part of the side surface of the semiconductor fin at the opening.

In some cases, the first mask pattern may be removed by a wet etching process using a hot phosphoric acid.

In some cases, forming the first inter-layer insulating film may include, but is

not limited to forming a polysilazane film.

In some cases, the first mask pattern may be removed while the liner film remains.

In some cases, the second liner portion may be interposed between the inter-layer insulating film and the gate insulating film. Removing the first mask pattern may include, but is not limited to, forming a recess at the top portion of the second liner portion, the recess is closer to the gate insulating film than to the inter-layer insulating film.

In some cases, the liner film may is a silicon oxynitride film which contains at least 11 atm % of nitrogen atoms. The number of oxygen atoms in the silicon oxynitride film may be at least two-times as many as the number of nitrogen atoms.

In some cases, the liner film may is a silicon oxynitride film which contains 13 atm % to 18 atm % of nitrogen atoms. The number of oxygen atoms in the silicon oxynitride film may be three-times to five-times as many as the number of nitrogen atoms.

In another embodiment, a method of forming a semiconductor device may include, but is not limited to, the following processes. A nitride mask is formed over a semiconductor substrate. The semiconductor substrate is selectively etched to form semiconductor pillars and grooves that define the semiconductor pillars. The semiconductor pillars extend upwardly from the semiconductor substrate. Gate insulating films are formed which cover the grooves, while the nitride mask remaining over the pillars. Gate electrodes are formed on the gate insulating films, while the nitride mask remains over the pillars. The gate electrodes are lower in top level than the semiconductor pillars. The gate electrode faces toward the semiconductor pillar through the gate insulating film. Liner films of silicon oxynitride are formed, which cover the grooves. Spin-on-dielectrics-interlayer insulating films are formed, which cover the liner films and fill the grooves. A heat treatment of the spin-on-dielectrics-interlayer insulating films is performed in an oxidation atmosphere to increase a film density of the spin-on-dielectrics-interlayer insulating film. The nitride mask is selectively removed.

In still another embodiment, a method of forming a semiconductor device may include, but is not limited to, the following processes. Semiconductor pillars and grooves are formed using a mask. The pillars are defined by the grooves. The pillars extend upwardly from a surface of a semiconductor substrate. Gate electrodes are formed which extend surrounding the semiconductor pillars. The gate electrode is lower in top level than the semiconductor pillar. Liner films are formed, which cover the gate electrodes. The liner film extends upwardly from the top of the gate electrode. The liner film extends along an upper portion of the side surface of the semiconductor pillar. The upper portion of the side surface is positioned over the top of the gate electrode. A first inter-layer insulating film is formed, which covers the liner film. A heat treatment is performed in an oxidation atmosphere to increase a film density of the first inter-layer insulating film. The mask is selectively removed. Contact plugs are formed over the semiconductor pillars and the liner films, while the liner films being present over the gate electrodes and separating the semiconductor pillars from the contact plugs.

In an additional embodiment, a semiconductor device may include, but is not limited to, a semiconductor substrate, and a plurality of semiconductor pillars which extend upwardly from the surface of the semiconductor substrate. A pair of top and bottom diffusion regions is disposed at a top portion of the semiconductor pillar and around the bottom of the semiconductor pillar. A gate insulating film is despised on a side surface of each semiconductor pillar. A gate electrode is disposed on the gate insulating film. The gate electrode surrounds the semiconductor pillar. The gate electrode faces toward the semiconductor pillar through the gate insulating film. The top surface of the gate electrode is lower than the semiconductor pillar. A liner film covers the side surface and the top surface of the gate electrode. The liner film may be made of a silicon oxynitride film. An inter-layer insulating film fills a gap between two adjacent liner films. The inter-layer insulating film projects from the semiconductor pillar. A contact plug covers the top surface of the semiconductor pillar. The contact plug fills a gap between the projecting portions of the inter-layer insulating films.

In some cases, the second liner portion is interposed between the inter-layer insulating film and the gate insulating film. A recess is present at the top portion of the second liner portion. The recess is closer to the gate insulating film than to the inter-layer insulating film.

In some cases, the semiconductor device may include, but is not limited to, a plurality of semiconductor pillars which are arrayed. The grooves define the semiconductor pillars. A first gate electrode surrounds the semiconductor pillar. The first diffusion region is disposed beneath the bottom portion of the semiconductor pillar. The second diffusion region is disposed at the upper portion of the semiconductor pillar.

In some cases, the second semiconductor device may further include, but is not limited to, base portions which extend in a first horizontal direction over the semiconductor substrate, and a plurality of second semiconductor pillars which extend upwardly from the base portion. The second semiconductor pillars are arrayed in the first direction and a second direction perpendicular to the first direction. The base portions are defined by second groves. Bit lines are disposed in the second grooves. Third diffusion regions are formed in the semiconductor substrate. The third diffusion regions contact the bit lines. A second gate insulating film is disposed on a side surface of the second semiconductor pillar. A second gate electrode faces toward the second semiconductor pillar through the second gate insulating film. A fourth diffusion region is disposed at the upper portion of the second semiconductor pillar.

In some cases, a first insulating film separates the bit line from the base portion. The first insulating film covers the second groove. An opening is formed at a lower portion of a side surface of the second groove. The opening extends in the second direction. The bit line and the third diffusion region contact each other at the opening.

In some cases, the first inter-layer insulating film may include, but is not limited to, a polysilazane film.

In some cases, the liner film contains at least 11 atm % of nitrogen atoms, and oxygen atoms. The number of oxygen atoms is at least two-times as many as the number of nitrogen atoms.

In some cases, the liner film contains 13 atm % to 18 atm % of nitrogen atoms, and oxygen atoms. The number of oxygen atoms is three-times to five-times as many as the number of nitrogen atoms.

### Embodiments

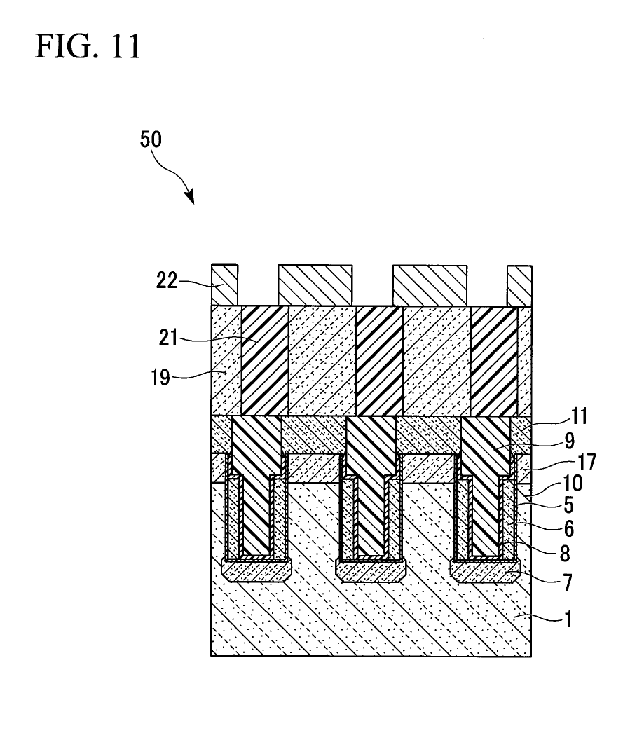

A semiconductor device 50 according to an embodiment of the present invention will be described with reference to FIG. 11. FIG. 11 is a cross-sectional view of the semiconductor device 50 according to an embodiment of the present invention vertically cut in a first direction (X-axis direction).

The semiconductor device 50 according to an embodiment of the present invention may include, but is not limited to, the following elements. First semiconductor pillars 10 are provided to stand on a semiconductor substrate 1. A first impurity diffusion layer 7 is formed on a lower layer of the first semiconductor pillar 10. A second impurity diffusion layer 17 is formed on an upper electrode of the first semiconductor pillar 10. A first gate electrode 6 is disposed on a side surface of the first semiconductor pillar 10. A first liner film 8 is formed. A first interlayer insulating film (SOD film) 9 is formed. A first contact plug 11 covering the second impurity diffusion layer 17 is formed.

### (First Semiconductor Pillar 10)

As illustrated in FIG. 11, the semiconductor substrate 1 is made of a P-type conductive silicon (Si). A plurality first semiconductor pillars 10 in the form of a pillar is provided to stand. The first semiconductor pillar 10 may be, but is not limited to, in the form of a tetragon in plan view. The first semiconductor pillar 10 may, for example, have a height of about 200 nm and widths of about 100 nm in both the first direction (X-axis direction) and the second direction (Y-axis direction). The first semiconductor pillars 10 stand in a row at the same interval of about 100 nm in the first direction (X-axis direction). A first groove 4 is formed to surround the circumference of the first semiconductor pillar 10.

### (First Impurity Diffusion Layer 7)

The first impurity diffusion layer 7 may be formed below the first gate insulating film of the lower layer portion of the first semiconductor pillar 10. The first impurity diffusion layer 7 may, for example, have a semiconductor structure in which arsenic is introduced as an N-type impurity. The first impurity diffusion layer 7 performs as one side of the source/drain electrodes of the vertical MOS transistor.

### (Second Impurity Diffusion Layer 17)

The second impurity diffusion layer 17 is formed on the upper layer portion of the first semiconductor pillar 10, and, for example, has a structure into which arsenic is introduced as an N-type impurity. The second impurity diffusion layer 17 performs as the other side of source/drain electrodes of the vertical MOS transistor.

### (First Gate Electrode 6)

The first gate electrode 6 may, for example, be formed of a phosphorous doped silicon film having a thickness of 30 nm. The first gate electrode 6 may have a surrounding gate structure that completely surrounds the outer periphery of the side wall of the first semiconductor pillar 10 via the first gate insulating film 5. Accordingly, the first gate electrode 6 may have a structure that is separated by the first gate insulating film 5 from the pillar portion 20d.

The material of the first gate electrode 6 is not limited to the phosphorous doped silicon film. The material of the first gate electrode 6 may be a polysilicon film into which impurities such as arsenic are introduced, or a high melting point film such as a titanium (Ti) film, a titanium nitride (TiN) film, a tantalum (Ta) film, a tantalum nitride (TaN) film, a tungsten (W) film, or the like. Also, a laminated body of the polysilicon film and the high melting point film may be used as the material of the first gate electrode 6.

Also, the upper portion of the first gate electrode 6 has a height that is lower than that of the upper portion of the first semiconductor pillar 10. Also, from the upper portion of the side surface of the first semiconductor pillar 10 to the upper surface of the first gate electrode 6, a first liner film 8 to be described later is formed to fill a gap between the first interlayer insulating film 9 and the first gate insulating film 5. Accordingly, the circumference of the first gate electrode 6 is covered with the first gate insulating film 5 and the first liner film 8.

### (First Liner Film 8)

The first liner film 8 may, for example, be made of a silicon oxynitride (SiON) film having a thickness of 10 nm. The first liner film 8 may be formed to cover the inner walls of the first groove 4. The inner walls are defined by the side surface and the upper surface of the first gate electrode 6 and the upper portion of the side surface of the first semiconductor pillar 10.

The compositional ratio of oxygen atoms O and nitrogen atoms N in the first liner film 8 can be adjusted through the change of the film forming condition, and it is preferable to appropriately adjust the compositional ratio according to the construction and manufacturing process.

As an example, in the case where a third interlayer insulating film (SOD film) 29 is made of polysilazane, it is preferable that the content of the nitrogen atoms in the second liner film (silicon oxynitride film) 18 is equal to or more than 11 atm %, and the number of oxygen atoms is twice or more the number of nitrogen atoms. Also, it is more preferable that the content of the nitrogen atoms in the second liner film (silicon oxynitride film) 18 is in the range of 13 to 18 atm %, and the number of oxygen atoms is three times to five times larger than the number of nitrogen atoms.

As shown in FIG. 8B, the first liner film 8 is formed so that the upper portion 8a of the first liner film on the side of the first gate insulating film 5 is more greater recessed than the upper portion 8a of the first liner film on the side of the first interlayer insulating film (SOD film) 9 to be described later. That is, the height h4 of the upper portion 8a of the first liner film on the side of the first gate insulating film 5 is smaller than the height h6 of the upper portion 8a of the first liner film on the side of the first interlayer insulating film 9. Also, the difference in height becomes smaller as the first liner film 8 becomes thinner.

Here, the upper portion 8a of the first liner film is recessed, for example, as far as the height h5 (10 nm) from the upper surface of the first semiconductor pillar 10, and is formed, for example, with a height of about 40 nm from the upper surface of the first gate electrode 6.

### (First Interlayer Insulating Film (SOD Film) 9)

The first interlayer insulating film 9 may, for example, be made of polysilazane. The first interlayer insulating film 9 may cover the first liner film 8. The first interlayer insulating film 9 may be formed to fill in the inside of the first groove 4. Also, the upper portion thereof is formed to project from the upper surface of the first semiconductor pillar 10.

The material of the first interlayer insulating film (SOD film) 9 is not limited to polysilazane. That is, the first interlayer insulating film is a coated insulation film that contains at least silicon atoms and nitrogen atoms, and it is sufficient if the first interlayer insulating film is a film in which Si—N bond is converted into Si—O bond as the first interlayer insulating film is exposed to high-temperature vapor (steam). Also, a material for densification may be used as the first interlayer insulating film through performing of heat treatment to the first interlayer insulating film under high-temperature oxygen (O₂) atmosphere.

### (First Contact Plug 11)

The first contact plug 11 may, for example, be formed of phosphorous doped silicon film. The first contact plug 11 may cover the second impurity diffusion layer 17. The first contact plug 11 may be formed to fill a gap between the first interlayer insulating films 9. The material of the first contact plug 11 is not limited to the phosphorous doped silicon film. The material of the first contact plug 11 may be a laminated body of an arsenic-doped silicon film, a titanium film, a titanium nitride film, a tantalum film, and the like.

### (Second Contact Plug 21)

The second interlayer insulating film 19 made of a silicon oxide film or the like is formed to cover the first interlayer insulating film 9 and the first contact plug 11. The second contact plug 21 is formed in the second interlayer insulating film 19. The second contact plug 21 is in contact with the upper surface of the first contact plug 11. The second contact plug 21 penetrates the second interlayer insulating film 19. Also, a first gate electrode 6 and a contact plug (not illustrated) that is not in contact with the first impurity diffusion layer 7 are formed.

Also, on the second contact plug 21, a metal interconnect 22, which is made of aluminum (Al), copper (Cu), tungsten (W), or the like, is formed. As described above, a semiconductor device 50 provided with vertical MOS transistors is constructed, and if any, an interconnect film or a protection film (not illustrated) may be further formed on the upper layer.

A method of manufacturing a semiconductor device 50 according to the first embodiment of the present invention will be described with reference to the accompanying drawings.

The method of manufacturing the semiconductor device 50 may include, but is not limited to, the following processes. A first mask nitride film (hard mask) 2 is formed. A first semiconductor pillar 10 is formed. A first gate electrode layer 6a is formed. A first gate electrode 6 is formed. A first impurity diffusion layer 7 is formed. A first liner film 8 is formed. A first interlayer insulating film 9 is formed. A heat treatment is performed to a first interlayer insulating film (SOD film) 9. A first mask nitride film 2 is removed. A second impurity diffusion layer 17 is formed. A first contact plug 11 is formed. A second contact plug 21 is formed. The details of the above-mentioned processes will be described hereinafter.

In the following descriptions, the drawings are illustrated in order to explain the method of manufacturing the semiconductor device 50 according to an embodiment of the present invention, and the size, thickness, and dimensions of respective portions as illustrated are different from those of an actual semiconductor device 50.

Also, “C” of each drawing indicates a plan view, and “A” of each drawing indicates a cross-sectional view vertically cut along a first direction (line X-X′).

### <First Process> (Process of Forming a First Mask Nitride Film 2)

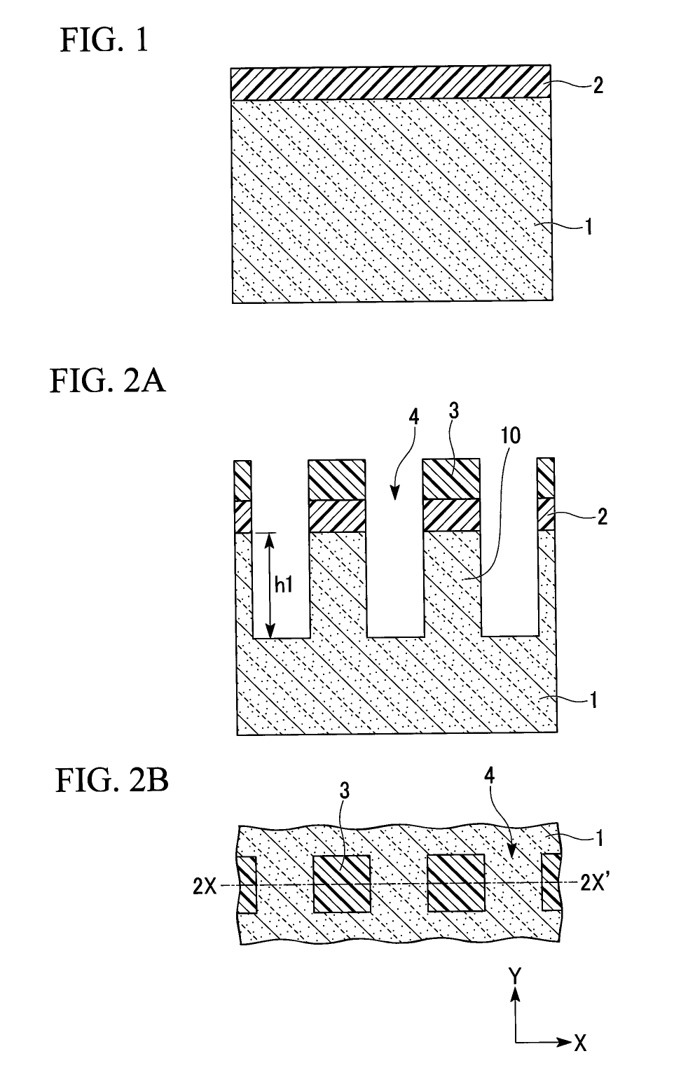

First, as illustrated in FIG. 1, a first mask nitride film (hard mask) 2 is formed. At first, a semiconductor substrate 1 made of P-type conductive silicon (Si) is prepared. Then, a first mask nitride film 2 made of a silicon nitride (Si₃N₄) film, for example, with a thickness of 50 nm is formed to cover the semiconductor substrate 1 by an LP-CVD (Low Pressure CVD) method. At this time, as a condition of the LP-CVD method, it is preferable that dichlorosilane (SiH₂Cl₂) and ammonia (NH₃) are used as source gases and reaction is performed at a high temperature of about 600° C. and under reduced pressure.

As described above, by using the LP-CVD method, the first mask nitride film 2 that contains about 55 atm % to 60 atm % of nitrogen atoms can be formed. The first mask nitride film 2 has anti-oxidation properties, and can be removed by wet etching using a phosphoric acid solution (H₃PO₄) that is heated to a temperature of about 150° C. to 160° C., hereinafter referred to as hot phosphoric acid. Accordingly, in the following process, only the first mask nitride film 2 can be selectively removed.

### (Process of Forming a First Semiconductor Pillar 10)

Then, as illustrated in FIGS. 2A and 2B, a first semiconductor pillar 10 is formed.

First, a first photoresist mask 3 is formed on the first mask nitride film 2. The first photoresist mask 3, as illustrated in FIG. 2B, is in the form of a tetragon in plan view, for example, with a width of about 100 nm in both an X-axis direction and a Y-axis direction. Also, the first photoresist mask 3 is formed to have patterns which stand in a row at the same interval of about 100 nm in the first direction (X-axis direction). By forming the first photoresist mask 3 at the above-described interval, it becomes possible to form vertical MOS transistors at high density. Also, in the following process, the vertical MOS transistors can be formed in respective regions that correspond to the pattern of the first photoresist mask 3.

Then, using the first photoresist mask 3 as a mask, the first mask nitride film 2 and the semiconductor substrate 1 are sequentially etched. In this case, the first mask nitride film 2 protects the upper surface of the first semiconductor pillar 10, and performs as a hard mask during patterning of the first semiconductor pillar 10. Also, the semiconductor substrate 1 is etched up to the depth of about h1=200 nm. Accordingly, a plurality of first semiconductor pillars 10, each of which is in the form of a tetragon in plan view with a width of about 100 nm in both an X-axis direction and a Y-axis direction, is formed to stand in a row at the same interval of about 100 nm in the first direction (X-axis direction). Also, a first groove 4 is formed to surround the circumference of the first semiconductor pillar 10.

<Second Process> (Process of Forming a First Gate Electrode Layer 6a)

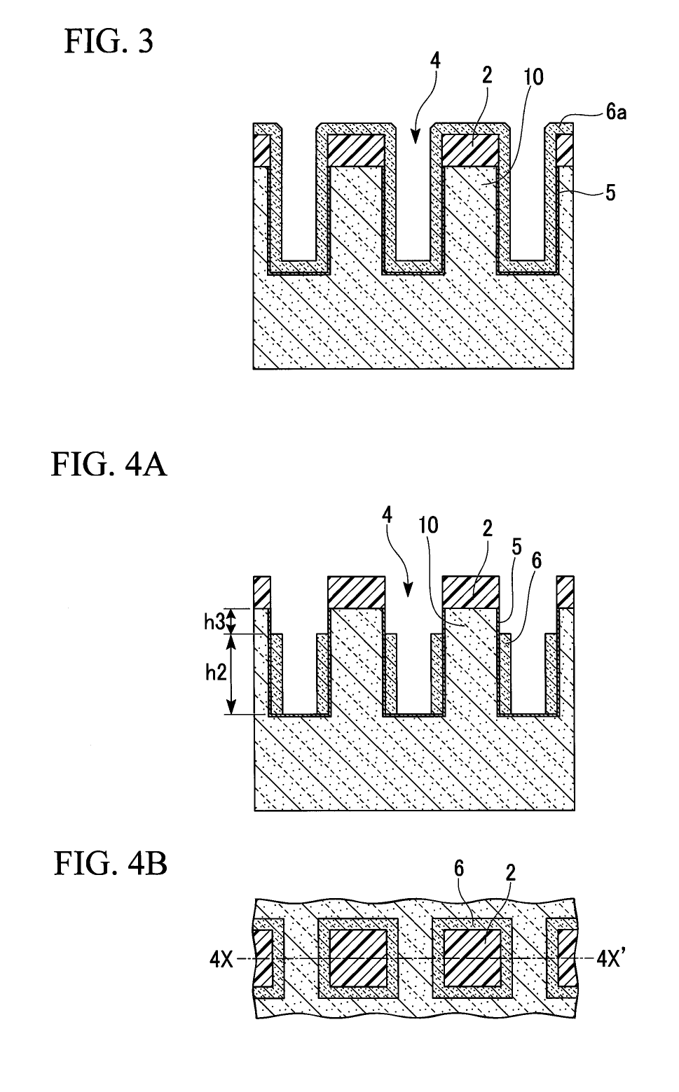

Then, as illustrated in FIG. 3, a first gate electrode layer 6a is formed.

First, the first photoresist mask 3 on the first semiconductor pillar 10 is removed. Then, for example, a first gate insulating film 5 composed of a silicon oxide (SiO₂) film with a thickness of 5 nm is formed to cover side surfaces and bottom surfaces of inner walls of the first groove 4, for example, by a thermal oxidation method. The material of the first gate insulating film 5 is not limited thereto, and may be a silicon oxynitride (SiON) film, a high-dielectric metal oxide film (high-K film), or a laminated body thereof. Also, the high-dielectric metal oxide film (high-K film) may be formed using the CVD method.

Then, the first gate electrode layer 6a composed of a polysilicon film (phosphorous doped silicon film) that contains, for example, phosphorous as an impurity is formed with a thickness of 30 nm to cover the inner wall surfaces of the first groove 4 and the first mask nitride film 2. In this case, the material of the first gate electrode layer 6a is not limited to the phosphorous doped silicon film, and may be a polysilicon film into which impurities such as arsenic are introduced, or a high melting point film such as a titanium (Ti) film, a titanium nitride (TiN) film, a tantalum (Ta) film, a tantalum nitride (TaN) film, a tungsten (W) film, or the like. Also, a laminated body of the polysilicon film and the high melting point film may be used.

### (Process of Forming a First Gate Electrode 6)

Then, as illustrated in FIGS. 4A and 4B, the first gate electrode 6 is formed.

First, by performing an anisotropic dry etching, the first gate electrode layer 6a is etched back on the bottom portion of the first groove 4 and the first mask nitride film 2. Accordingly, the first gate electrode layer 6a on the bottom portion of the first groove 4 and the first mask nitride film 2 is removed. The first gate electrode 6 is formed, which is separated by the first gate insulating film 5 from the first semiconductor pillar 10. The first gate electrode 6 covers the side walls of the first semiconductor pillar 10. In this embodiment of the present invention, the first gate electrode 6 has a surround gate structure that completely surrounds the outer periphery of the channel region (first semiconductor pillar 10) of the vertical MOS transistor.

In this case, the height h2 of the first gate electrode 6, may, for example, be set to about 150 nm, and the height h3 of a portion, on which the first gate insulating film 5 is exposed, of the side surface of the upper portion of the first semiconductor pillar 10 is set to about 50 nm.

### <Third Process> (Process of Forming a First Impurity Diffusion Layer 7)

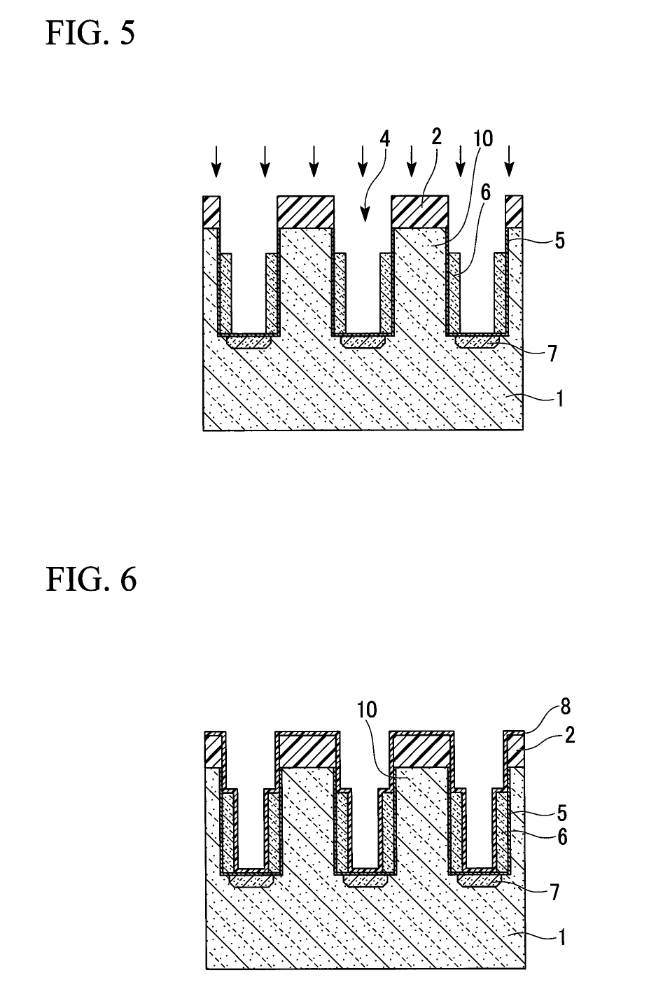

Then, as illustrated in FIG. 5, an impurity injection is performed onto the semiconductor substrate 1 that is positioned below the bottom portion of the first groove 4 via the first gate insulating film 5. Accordingly, a first impurity diffusion layer 7 is formed below the first gate insulating film 5 of the lower layer portion of the first semiconductor pillar 10. In this case, the impurity introduction is performed by injecting arsenic, for example, with energy of 20 Kev and doze of 1×10¹⁵ atoms/cm² using an ion injection method. This first impurity diffusion layer 7 performs as one side of the source/drain electrodes of the vertical MOS transistor.

### (Process of Forming a First Liner Film 8)

Then, as illustrated in FIG. 6, a first liner film 8 composed of a silicon oxynitride (SiON) film is formed, for example, with a thickness of 10 nm to cover the inner walls of the first groove 4 and the first mask nitride film 2. At this time, the forming of the first liner film 8 is performed using the LP-CVD method and by reacting dichlorosilane (SiH₂Cl₂), nitrous oxide (N₂O), and ammonia (NH₃) as source gases at a high temperature of about 600° C. and under reduced pressure.

At this time, by changing the flow ratio of the source gases, the compositional ratio of oxygen atoms O and nitrogen atoms N in the first liner film 8 can be adjusted. By this, it becomes possible to change the anti-oxidation properties of the first liner film 8 and the tolerance against the wet etching in the following processes.

By increasing the compositional ratio of nitrogen atoms, the anti-oxidation properties and the oxygen penetration prevention function of the first liner film (silicon oxynitride film) 8 are improved. However, on the other hand, the tolerance against the wet etching by the hot phosphoric acid deteriorates. Accordingly, it is sufficient if the first liner film (silicon oxynitride film) 8 is formed in the optimum compositional ratio in consideration of both a condition of the heat treatment process of the first interlayer insulating film (SOD film) 9 to be described later and a condition of the wet etching by the hot phosphoric acid.

As a concrete example, in the case where the first interlayer insulating film (SOD film) 9 is formed of polysilazane in the following process, it is preferable to use the silicon oxynitride film, in which the content of the nitrogen atoms is equal to or more than 11 atm %, and the number of oxygen atoms is twice or more the number of nitrogen atoms, as the first liner film 8. Also, it is more preferable from the viewpoint of the balance between the anti-oxidation properties and the wet etching tolerance to use the silicon oxynitride film, in which the content of the nitrogen atoms is in the range of 13 to 18 atm %, and the number of oxygen atoms is three times to five times the number of nitrogen atoms, as the first liner film 8.

In a process of forming the first interlayer insulating film 9, a process of annealing the first interlayer insulating film 9, and a subsequent heat treatment process to be described later, it is necessary to form the first liner film 8 to prevent the invasion of oxygen into the semiconductor substrate 1 and the first gate electrode 6.

If the first liner film 8 is not formed, oxygen invades and oxidizes the semiconductor substrate 1 or the first gate electrode 6 in the above-described processes. Due to this, resistance of the first gate electrode 6 and the first impurity diffusion layer 7 to be described later is increased. Also, if the first liner film 8 does not exist, a defect occurs in crystal of the semiconductor substrate 1 due to the expansion of the accumulation of the first gate electrode 6 or the semiconductor substrate 1, and there occurs the problems that the resisting pressure of the first gate insulating film 5 is lowered. Due to this, it is necessary to form the first liner film 8 composed of a silicon oxynitride film as a film which has the anti-oxidation properties and can suppress the penetration of oxygen.

### (Process of Forming a First Interlayer Insulating Film 9)

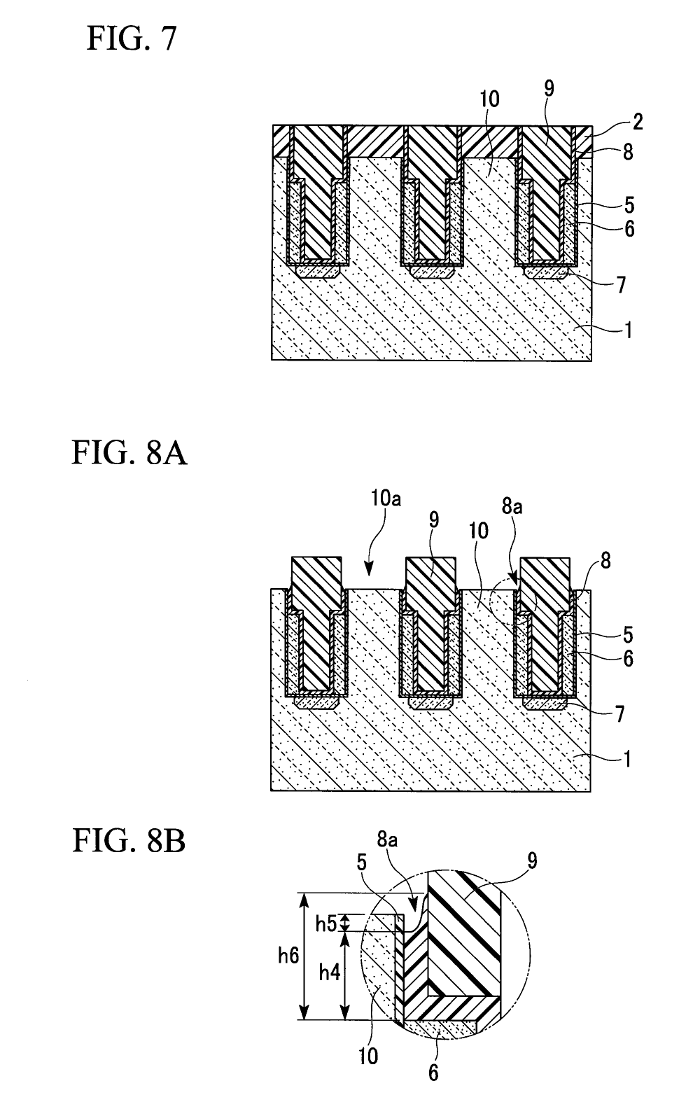

Then, as illustrated in FIG. 7, a first interlayer insulating film 9 is formed. First, the first interlayer insulating film 9 made of polysilazane is coated to cover the first liner film 8 and to fill in the first groove 4.

Polysilazane, which is also called silazane type polymer, is a macromolecular material having [—(SiH₂—NH)—] as its basic structure, and is dissolved in a solvent (xylene, di-n-butyl ether, and the like) to be used. Also, the silazane type polymer includes a material in which hydrogen has been substituted by another functional group such as a methoxy group or the like. Also, the silazane type polymer to which no functional group or modified group is added is called perhydropolysilazane.

By using the polysilazane as the first interlayer insulating film (SOD film) 9, it is possible to fill in space having a high aspect ratio such as the first groove 4 in a state where cavities (voids) does not occur.

Also, the material of the first interlayer insulating film (SOD film) 9 is not limited to polysilazane. That is, the first interlayer insulating film is a coated insulation film that contains at least silicon atoms and nitrogen atoms, and it is sufficient if the first interlayer insulating film is a film in which Si—N bond is converted into Si—O bond as the first interlayer insulating film is exposed to high-temperature vapor (steam). Also, a material for densification may be used as the first interlayer insulating film through performing of heat treatment to the first interlayer insulating film under high-temperature oxygen (O₂) atmosphere.

### <Fourth Process> (Process of Performing Heat Treatment to a First Interlayer Insulating Film (SOD Film) 9)

Then, by performing annealing process for 60 minutes under oxidation atmosphere including vapor (H₂O) at a high temperature of 700° C., the film density of the first interlayer insulating film (SOD film) 9 is increased. By heating the coated film that contains nitrogen such as polysilazane or the like under high-temperature vapor (steam) atmosphere, nitrogen in the coated film reacts on hydrogen in vapor to produce ammonia (NH₃) gas, and the ammonia gas secedes from the coated film. Accordingly, Si—N bond in the coated film is substituted by Si—O bond, and the first interlayer insulating film is modified into a film having an increased film density and having silicon oxide (SiO₂) as a main component.

At this time, in the case where the first interlayer insulating film (SOD film) 9 is made of a material that increases in its film density through the heat treatment under high-temperature oxygen (O₂) atmosphere, the heat treatment is performed under the high-temperature oxygen (O₂) atmosphere.

Also, the temperature and the time in the annealing process can be changed according to the kind of the first interlayer insulating film (SOD film) 9. Also, since the annealing process functions to exclude impurities such as carbon in the first interlayer insulating film (SOD film) 9, the deterioration of the device characteristics due to the impurities having invaded into the semiconductor substrate 1 can be prevented.

During the annealing process, the semiconductor substrate 1 is exposed under vapor atmosphere or oxygen atmosphere. However, since the first liner film 8 is formed on the lower layer of the first interlayer insulating film (SOD film) 9, the oxidation of the semiconductor substrate 1 and the first gate electrode 6 can be prevented.

In the case of using a metal material of high melting point such as tungsten or the like as the material of the first gate electrode 6, the resistance value of the first gate electrode 6 becomes lower than that of the polysilicon, but the first gate electrode is affected by the oxidation more easily than the polysilicon. However, in this embodiment of the present invention, the silicon oxynitride film is formed as the first liner film 8, and thus even in the case where a metal material of high melting point is used as the first gate electrode 6, its oxidation can be prevented.

Thereafter, the upper surface of the first mask nitride film 2 is exposed by removing the surface of the first interlayer insulating film (SOD film) 9 and the first liner film 8 on the first mask nitride film 2 through grinding using a CMP method. In this case, the method of exposing the upper surface of the first mask nitride film 2 is not limited to the CMP method, and etch back may be performed using a dry etching technology.

### (Process of Removing a First Mask Nitride Film 2)

Then, as illustrated in FIG. 8A, the first mask nitride film 2 is selectively removed by wet etching using a hot phosphoric acid solution (H₃PO₄). Here, since the first semiconductor pillar 10 is patterned by the pattern of the first mask nitride film 2, the whole upper surface of the first semiconductor pillar 10 is exposed by removing the first mask nitride film 2. Also, by exposing the upper surface of the first semiconductor pillar 10, a first semiconductor pillar opening portion 10a is formed in self-alignment manner.

Accordingly, in the processes to be described later, a second impurity diffusion layer 17 can be uniformly formed on the first semiconductor pillar opening portion 10a. Accordingly, it is possible to use the upper portion of the first semiconductor pillar 10 as the source/drain electrodes.

During the wet etching, the etching speed of the hot phosphoric acid solution (H₃PO₄) was about 5 nm/minute with respect to the silicon nitride film. During the wet etching of the first mask nitride film 2, it is necessary to perform over-etching in addition to the etching of up to the depth of the first mask nitride film 2 in consideration of the difference in film thickness of the film in the manufacturing process. For example, in the case of adding 100% of over-etching with respect to the thickness of the first mask nitride film 2, the etching is performed for about 20 minutes to the extent that can remove 100 nm of the nitride film. That is, it is necessary to add the over-etching to the extent that can further etch 50 nm of the nitride film after the first mask nitride film 2 having a thickness of 50 nm is removed.

When the over-etching is performed, the first liner film (SiON film) 8 is also exposed to the hot phosphoric acid solution, and thus the upper portion thereof is etched. As a result of evaluating the etching speed of the SiON film by the hot phosphoric acid solution, it was found by inventor's experiments that the etching speed of the SiON film according to the embodiment of the present invention was about 1 nm/minute, which was about ⅕ of the etching speed of the silicon nitride film. Accordingly, in the case of performing 100% of over-etching with respect to the first mask nitride film 2 on the above-described condition, the upper surface of the first liner film (SiON film) 8 (the upper portion 8a of the first liner film) is recessed as far as about 10 nm from the upper surface of silicon of the first semiconductor pillar 10.

FIG. 8B is an enlarged view of a portion ranging from the first semiconductor pillar opening portion 10a to the first gate electrode 6. In this embodiment of the present invention, even if the etching and over-etching of up to the extent that can remove 100 nm of nitride film 2 has been performed with respect to the first mask nitride film 2 having a thickness of 50 nm, the upper portion 8a of the first liner film is recessed only for a distance of h5=10 nm from the upper surface of the first semiconductor pillar 10. Accordingly, the first liner film 8 may remain for about h4=40 nm from the first gate electrode 6.

After the wet etching is performed, the first liner film (SiON film) 8 is shaped so that the upper portion 8a of the first liner film on the side of the first semiconductor pillar 10 is more greatly recessed than the upper portion 8a of the first liner film on the side of the first interlayer insulating film 9. That is, if it is assumed that the height of the upper portion 8a of the first liner film on the side of the first semiconductor pillar 10 from the upper surface of the first gate electrode 6 is h4, and the height from the upper surface of the first gate electrode 6 on the side of the first interlayer insulating film 9 is h6, h6 becomes larger than h4. This is because the first liner film 8 is etched from a portion that is close to the first mask nitride film 2 after the first mask nitride film 2 is etched. Accordingly, as the first liner film 8 becomes thinner, the difference between h4 and h6 after the wet etching becomes smaller and thus the upper portion 8a of the first liner film approximates to the flatness.

### (Process of Forming a Second Impurity Diffusion Layer 17)

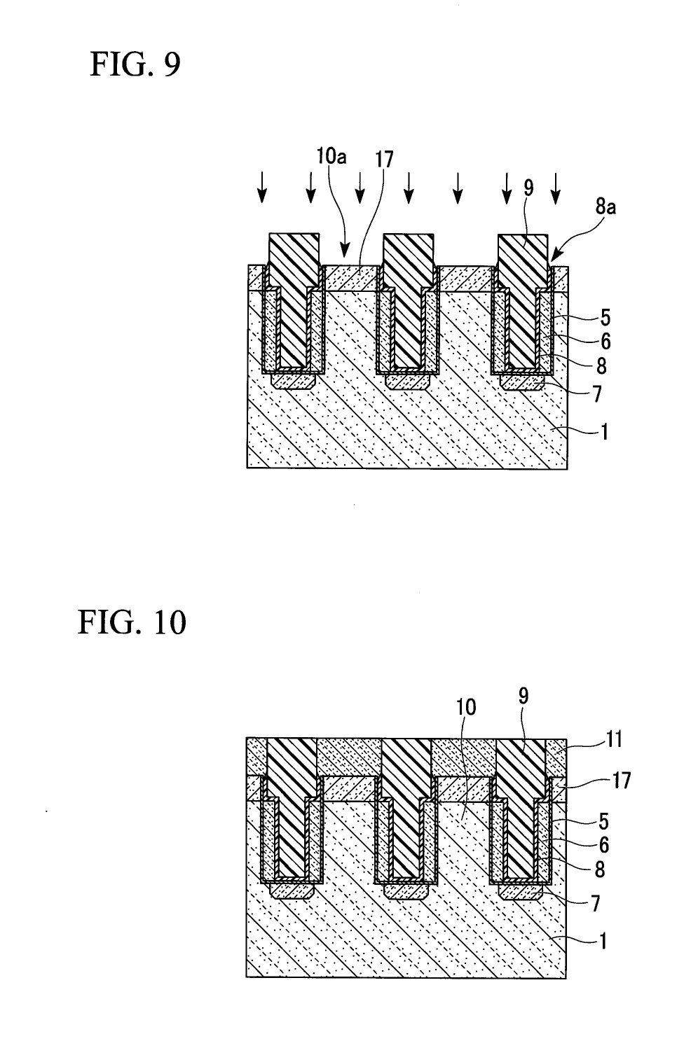

Then, as illustrated in FIG. 9, for example, arsenic is introduced onto the upper surface of the first semiconductor pillar 10 by ion injection on a condition of energy of 10 Kev and doze of 1×10¹⁵ atoms/cm². Accordingly, a second impurity diffusion layer 17 is formed on the upper layer of the first semiconductor pillar 10. This second impurity diffusion layer 17 performs as the other side of the source/drain electrodes of the vertical MOS transistor.

### (Process of Forming a First Contact Plug 11)

Then, as illustrated in FIG. 10, the first contact plug 11 is formed. First, phosphorous doped silicon (first contact plug 11) is formed to cover the first semiconductor pillar 10 and to fill the first semiconductor pillar opening portion 10a. In this case, the material of the first contact plug 11 is not limited to the phosphorous doped silicon film, and may be a laminated body of an arsenic-doped silicon film, a titanium film, a titanium nitride film, a tantalum film, and the like.

Then, the upper surface of the first interlayer insulating film 9 is exposed by removing the upper surface of the phosphorous doped silicon film (first contact plug 11) through grinding using a CMP method. In this case, the method of exposing the upper surface of the first interlayer insulating film 9 is not limited to the CMP method, and etch back may be performed using a dry etching technology. Accordingly, the first contact plug 11 is formed.

### (Process of Forming a Second Contact Plug 21)

Then, as illustrated in FIG. 11, the second contact plug 21 is formed. First, a second interlayer insulating film 19 made of a silicon oxide film or the like is formed to cover the first interlayer insulating film 9 and the first contact plug 11.

Then, by performing annealing through lamp heating, the first impurity diffusion layer 7 and the second impurity diffusion layer 17 are activated. At this time, the annealing condition is under a nitrogen (N2) atmosphere, at 900° C. for 30 seconds. Accordingly, the first impurity diffusion layer 7 is diffused up to the portion of the semiconductor substrate 1 below the first gate electrode, and the second impurity diffusion layer 17 is diffused up to the position beside the first gate electrode 6. Accordingly, the upper layer portion of the first semiconductor pillar 10 includes the second impurity diffusion layer 17, and the lower layer portion thereof includes the first impurity diffusion layer 7.

Then, using the known method, the second contact plug 21 is formed, which is in contact with the upper surface of the first contact plug 11 and penetrates the second interlayer insulating film 19. Then, a contact plug (not illustrated) is formed, which is in contact with the first gate electrode 6 and the first impurity diffusion layer 7. In the process of manufacturing the contact plug (not illustrated), an interconnect for drawing out, which is in contact with the first gate electrode 6, is formed in advance, and a method of connecting the contact plug to the interconnect for drawing out may be used.

Then, a metal interconnect 22 is formed on the second contact plug 21. As the material of the metal interconnect 22, aluminum (Al), copper (Cu), tungsten (W), and the like, may be used.

Thereafter, by further forming an interconnect film (not illustrated) on the upper layer and a protection film on the surface, if necessary, the semiconductor device 50 provided with the vertical MOS transistors is completed.

In this embodiment of the present invention, by forming the first liner film 8 with a silicon oxynitride film (SiON film), the removal of the first liner film 8 can be suppressed when the first mask nitride film 2 is etched and over-etched. Accordingly, the upper surface of the first gate electrode 6 is prevented from being exposed. Due to this, it becomes possible to prevent a short circuit between the first gate electrode 6 and the electrode or the contact plug that is in contact with the upper surface of the first semiconductor pillar 10.

Also, the distance ranging from the upper surface of the first gate electrode 6 to the upper surface of the first liner film 8 remains sufficiently in comparison to the method in the related art, and thus the insulation of the first gate electrode 6 can be sufficiently secured.

Also, since the removal of the first liner film 8 is suppressed in the case of etching the first mask nitride film 2, it is possible to lengthen the etching time until the upper surface of the first gate electrode 6 is exposed as compared with the etching time in the related art. Through this, the first mask nitride film 2 on the upper surface of the first semiconductor pillar 10 is completely removed, and thus the etching remainder of the first mask nitride film 2 can be prevented.

Also, in this embodiment of the present invention, by making the phosphorous doped silicon film (the first contact plug 11) fill a gap between the first semiconductor pillars 10, the first contact plug 11 is formed. Due to this, the manufacturing difference in contact area between the first semiconductor pillar 10 and the first contact plug 11 can be reduced. Accordingly, the difference in contact resistance can be suppressed.

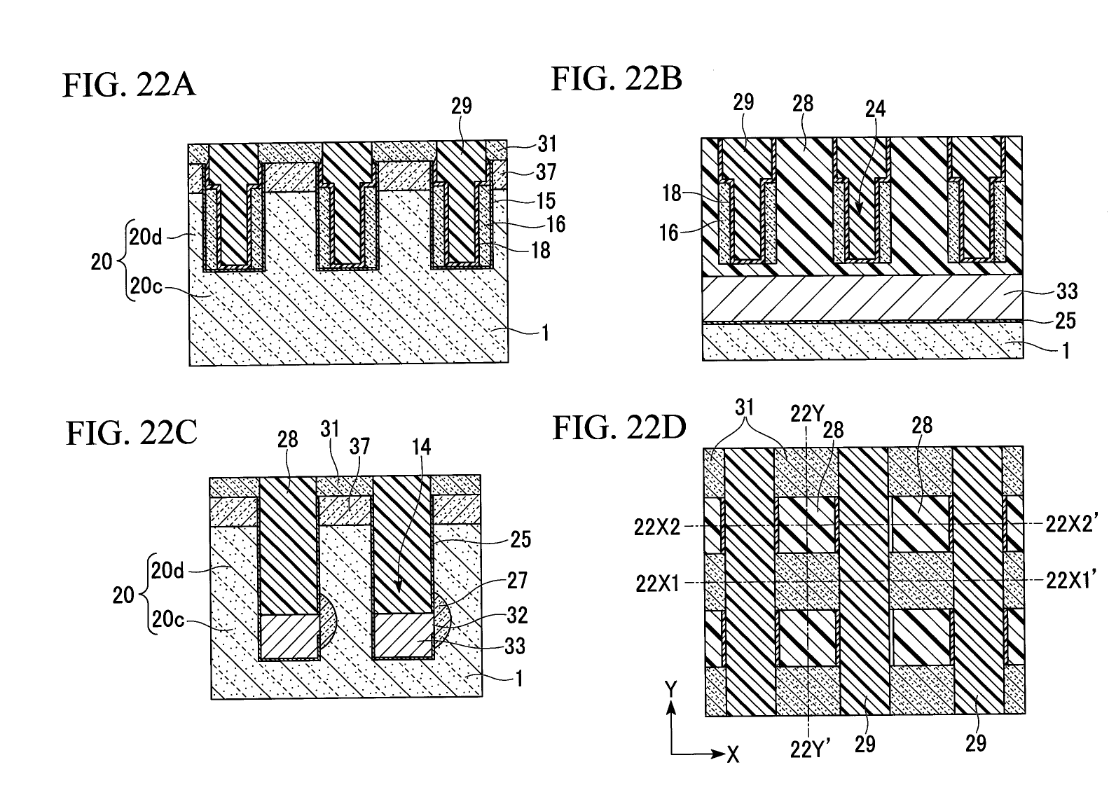

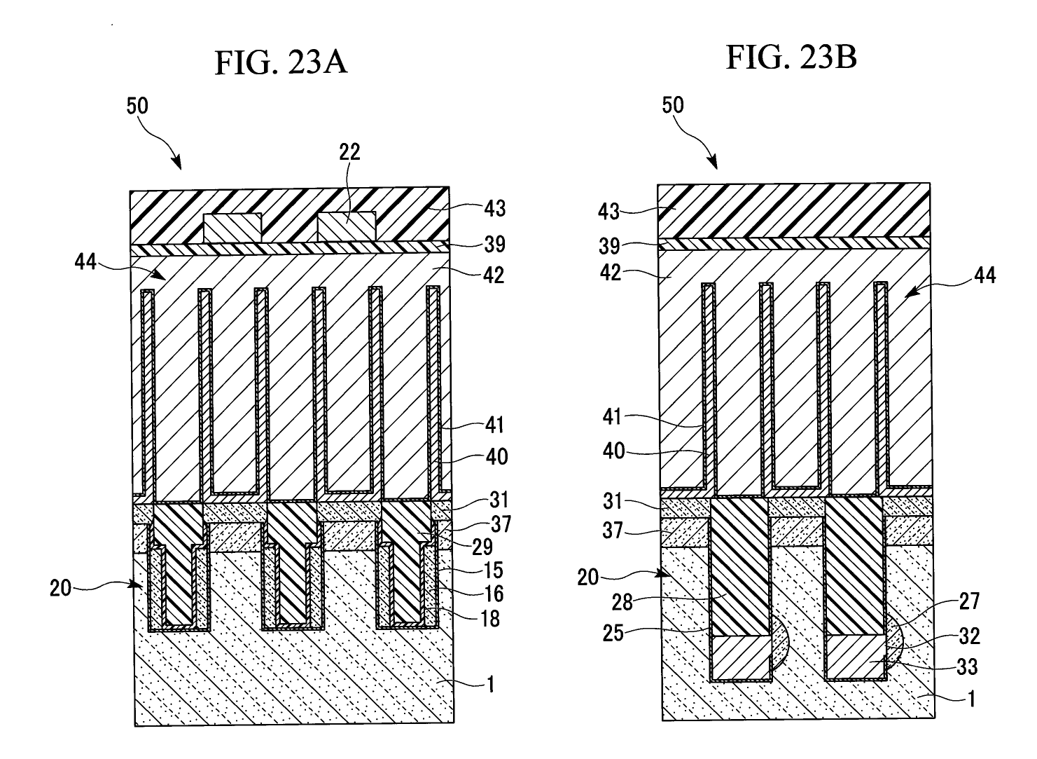

Then, the semiconductor device 50 according to this embodiment of the present invention will be described with reference to FIGS. 22A to 22D, 23A and 23B. FIG. 22A is a cross-sectional view vertically cut along the first direction (line 22X1-22X1′) of FIG. 22D, FIG. 22B is a cross-sectional view vertically cut along the first direction (line 22X2-22X2′) of FIG. 22D, and FIG. 22C is a cross-sectional view vertically cut along the second direction (line 22Y-22Y′) of FIG. 22D. Also, FIG. 23A is a cross-sectional view vertically cut along the first direction (line X1-X1′) of the semiconductor device 50, and FIG. 23B is a cross-sectional view vertically cut along the second direction (line Y-Y′) of the semiconductor device 50.

The semiconductor device 50 according to this embodiment of the present invention includes a second semiconductor pillar 20 composed of a base 20c provided to stand on a semiconductor substrate 1 and a pillar portion 20d provided to stand on the base 20c, a second gate insulating film 15 arranged on the side surface of the pillar portion 20d, a second groove 14 formed between the bases 20c, a bit line 33 formed on a lower layer portion (in the neighborhood of a bottom portion) on one surface side in the second groove 14, a third impurity diffusion layer 27 formed on a position that is in contact with the bit line 33 of the base 20c, a second gate electrode 16 configured to cover side walls of the pillar portion 20d and an embedded insulating film 28, a second liner film 18, a third interlayer insulating film (SOD film) 29, a fourth impurity diffusion layer 37 formed on the upper surface of the second semiconductor pillar 20 (pillar portion 20d), a third contact plug 31 covering the fourth impurity diffusion layer 37, and a capacitor element 44. Hereinafter, the respective constituent elements will be described in detail.

In the following description, the referred drawings are to explain the method of manufacturing the semiconductor device 50 according to this embodiment of the present invention, and the size, thickness, and dimensions of respective portions as illustrated are different from those of an actual semiconductor device 50.

### (Second Semiconductor Pillar 20)

As illustrated in FIGS. 22A to 22D, the semiconductor substrate 1 is made of a P-type conductive silicon (Si), and includes a base portion 20b composed of a flat surface, the base 20c provided on the base portion 20b, and a plurality of pillar portions 20d in the form of pillars provided on the base 20c. Among them, the base 20c and the pillar portions 20d constitute the second semiconductor pillar 20.

The base 20c is in the form of a fin, and extends in the first direction (X1) on the base portion 20b. Also, the base 20c is formed as a base of the pillar-shaped pillar portion 20d.

Also, the pillar portion 20d, which is in the form of a pillar, has a tetragonal shape in plan view of 50 nm in length and breadth. A plurality of pillar portions 20d is provided to stand at the same interval on the base 20c. Accordingly, the pillar portions 20d are arranged in the form of a matrix in the first direction (X1) and the second direction (Y).

### (Second Gate Insulating Film 15)

As illustrated in FIGS. 22A to 22D, for example, the second gate insulating film 15, which is made of a silicon oxide (SiO₂) film with a thickness of 5 nm, is formed to cover the upper surface of the base 20c and the side surface of the pillar portion 20d. Here, the material of the second gate insulating film 15 is not limited to the silicon oxide film, and may be a silicon oxynitride (SiON) film, a high-dielectric metal oxide film (high-K film), or a laminated body thereof.

### (Second Groove 14)

As illustrated in FIG. 22C, the second groove 14 is formed between the bases 20c, and extends in the first direction (X2) on the base portion 20b. Also, a first insulating film 25, which is composed of a first insulating film 25a formed on the side surface of the second groove 14 and a first insulating film 25b formed on the bottom surface of the second groove 14, is formed to cover the inner side of the second groove. Among them, in the lower layer portion (in the neighborhood of the bottom portion) on one surface side of the first insulating film 25a, for example, in a portion having a height of about 70 nm from the bottom portion of the second groove 14, an opening portion (which is described as a bit-line contact 32) is formed to extend in the second direction (Y direction).

### (Bit Line 33)

As illustrated in FIG. 22C, the bit line 33 composed of a conductor is formed to embed in the lower layer portion of the inside of the second groove 14. Here, the bit line 33 is embedded up to a height at which it covers at least a portion of the opening portion (bit-line contact 32). Accordingly, the bit line 33 is configured to be in contact with the second semiconductor pillar 20 through the bit-line contact 32. Also, the embedded insulating film 28 made of a silicon oxide film is formed to cover the bit line 33 and to fill in the second groove 14.

### (Third Impurity Diffusion Layer 27)

As illustrated in FIG. 22C, the third impurity diffusion layer 27 is included in the lower layer portion (base 20c) on one surface side of the second semiconductor pillar 20. This is because arsenic included in the bit line 33 is diffused from the opening portion (bit-line contact 32) of the first insulating film 25a to form a third impurity diffusion layer 27. Here, phosphorous may be used as an N-type impurity to form the third impurity diffusion layer 27. Also, the third impurity diffusion layer 27 performs as one side of the source/drain electrodes of the vertical MOS transistor constituting a memory cell.

### (Second Gate Electrode 16)

As illustrated in FIGS. 22A to 22D, for example, the second gate electrode 16 made of a phosphorous doped silicon film having a thickness of 30 nm covers the side walls of the second semiconductor pillar 20 (pillar portion 20d) and the embedded insulating film 28 via the second gate insulating film 15, and extends in the second direction (Y direction). Accordingly, the second gate electrode 16 is separated by the second gate insulating film 15 from the pillar portion 20d.

Also, the material of the second gate electrode 16 is not limited to the doped silicon film, and may be a high melting point film or a laminated film of the doped silicon film and the high melting point film. Since the second gate electrode 16 is used as the word line of the memory cell, it is preferable to use a material having low resistance.

The upper portion of the second gate electrode 16 is lower than the upper portion of the second semiconductor pillar 20. Also, on an area ranging from the upper portion of the side surface of the second semiconductor pillar 20 (pillar portion 20d) to the upper surface of the second gate electrode 16, the second liner film 18 to be described later is formed to fill a gap between the third interlayer insulating film 29 and the second gate insulating film 15. Accordingly, the circumference of the second gate electrode 16 is covered by the second gate insulating film 15 and the second liner film 18 to be described later.

### (Second Liner Film 18)

As illustrated in FIGS. 22A to 22D, for example, the second liner film 18 made of a silicon oxynitride film (SiON film) with a thickness of 8 nm is formed to cover the inner wall surfaces of the third groove 24 (the side surface and the upper surface of the second gate electrode 16 and the upper portion of the side surface of the pillar portion 20d).

The compositional ratio of oxygen atoms O and nitrogen atoms N in the second liner film 18 can be adjusted, and it is preferable to appropriately adjust the compositional ratio according to the construction and manufacturing process. For example, in the case where the third interlayer insulating film (SOD film) 29 is made of polysilazane, it is preferable that the content of the nitrogen atoms in the second liner film (silicon oxynitride film) 18 is equal to or more than 11 atm %, and the number of oxygen atoms is twice or more the number of nitrogen atoms. Also, it is more preferable that the content of the nitrogen atoms in the second liner film (silicon oxynitride film) 18 is in the range of 13 to 18 atm %, and the number of oxygen atoms is three times to five times the number of nitrogen atoms.

As shown in FIG. 22A, the second liner film 18 is formed so that the upper portion 18a of the second liner film on the side of the second gate insulating film 15 is more greatly recessed than the upper portion 18a of the second liner film on the side of the third interlayer insulating film 29 to be described later. That is, the height of the upper portion 18a of the second liner film on the side of the second gate insulating film 15 is larger than the height of the upper portion 18a of the second liner film on the side of the third interlayer insulating film 29. Also, the difference in height becomes smaller as the second liner film 18 is thinner.

Here, the upper portion 18a of the second liner film is recessed, for example, as far as 10 nm from the upper surface of the second semiconductor pillar 20 (upper surface of the pillar portion 20d), and is formed, for example, with a height of about 40 nm from the upper surface of the second gate electrode 16.

### (Third Interlayer Insulating Film 29)

As illustrated in FIGS. 22A to 22D, for example, the third interlayer insulating film (SOD film) 29 made of polysilazane is formed to cover the second liner film 18 and to fill in the third groove 24. Accordingly, the third interlayer insulating film 29 extends in the second direction (Y direction).

### (Fourth Impurity Diffusion Layer 37)

As illustrated in FIGS. 22A to 22D, the fourth impurity diffusion layer 37 is formed on the upper portion of the second semiconductor pillar 20 (upper portion of the pillar portion 20d). For example, arsenic is introduced to the fourth impurity diffusion layer 37 as an impurity. Also, the fourth impurity diffusion layer 37 performs as the other side of the source/drain electrodes of the vertical MOS transistor constituting a memory cell.

### (Third Contact Plug 31)

As illustrated in FIGS. 22A to 22D, for example, a third contact plug 31 made of a phosphorous doped silicon film is formed to cover fourth impurity diffusion layer 37. The material of the third contact plug 31 is not limited to the phosphorous doped silicon film, and may be an arsenic-doped silicon film or a laminated body of a titanium film, a titanium nitride film, and a tungsten film.

### (Capacitor Element 44)

As illustrated in FIGS. 23A and 23B, the capacitor element 44 is composed of a first capacitor electrode (lower electrode) 40, a capacitance insulating film 41, and a second capacitor electrode (upper electrode) 42.

The first capacitor electrode (lower electrode) 40 is formed on the third contact plug 31, and has a bottom portion and an upper portion that is in an open hollow tube shape. The capacitance insulating film 41 is made of a high dielectric film of zirconium oxide (ZrO₂), hafnium oxide (HfO₂), aluminum oxide (Al₂O₃), and the like, or their laminated film, and is formed to cover the outer and inner walls and a bottom surface of the first capacitor electrode 40. Also, for example, the second capacitor electrode 42 made of a metal film such as titanium nitride is formed to cover the first capacitor electrode 40 and the capacitance insulating film 41.

On the second capacitor electrode 42, a fourth interlayer insulating film 39 is formed to cover the second capacitor electrode 42. Also, a contact plug (not illustrated), which penetrates the respective interlayer insulating films and is in contact with the second gate electrode 16 and the bit line 33, is formed. Also, a metal interconnect 22 that is in contact with the contact plug is formed on the fourth interlayer insulating film 39, and a protection film 43 is further formed to cover the metal interconnect 22. Through the above-described construction, a memory cell of a DRAM device is formed.

Also, the construction of the bit line 33 or the capacitor element 44 described in this embodiment of the present invention is exemplary, and can be modified without departing from the scope and spirit of the present invention.

Also, instead of the capacitor element 44, a memory cell composed of a storage element of which the resistance value can be varied by an input of an electric signal and a vertical MOS transistor may be used. Specifically, examples of such a memory cell include a phase change memory element (PRAM) and a resistance change memory element (ReRAM).

In this embodiment of the present invention, as illustrated in FIG. 22A, the second gate electrodes (word lines) 16 are arranged so that a channel area of each transistor is inserted between the second gate electrodes 16. Accordingly, the existence/nonexistence of charge that is maintained in the capacitor element 44 can be determined through the bit line 33 connected to the vertical MOS transistor. Accordingly, the DRAM device according to this embodiment of the present invention can perform storage operation of information.

Hereinafter, a method of manufacturing a semiconductor device 50 according to a second embodiment of the present invention will be described with reference to the accompanying drawings. In the second embodiment of the present invention, a method of forming a DRAM memory cell using the vertical MOS transistor is provided.

The method of manufacturing a semiconductor device 50 according to this embodiment of the present invention includes a process of forming a convex portion 20a, a process of forming a bit line 33 and a third impurity diffusion layer 27, a process of forming an embedded insulating film 28, a process of forming a third photoresist mask 23, a process of forming a second semiconductor pillar 20 (first process), a process of forming a second gate electrode 16 (second process), a process of forming a second liner film 18, a process of forming a third interlayer insulating film 29 (third process), a process of removing a second mask nitride film 12 (fourth process), a process of forming a fourth impurity diffusion layer 37, a process of forming a third contact plug 31, and a process of forming a capacitor element 44. The details of the above-described processes will be described hereinafter, but the same portions as those in the first embodiment of the present invention will be omitted.

In this case, “C” of each drawing indicates a plan view, “A1” indicates a cross-sectional view vertically cut along a first direction (line X1-X1′), “A2” indicates a cross-sectional view vertically cut along a first direction (line X2-X2′), and “B” indicates a cross-sectional view vertically cut along a second direction (line Y-Y′). Also, the first direction (line X1-X1′) and the second direction (line Y-Y′) or the first direction (line X2-X2′) and the second direction (line Y-Y′) cross each other.

<First Process> (Process of Forming a Convex Portion 20a)

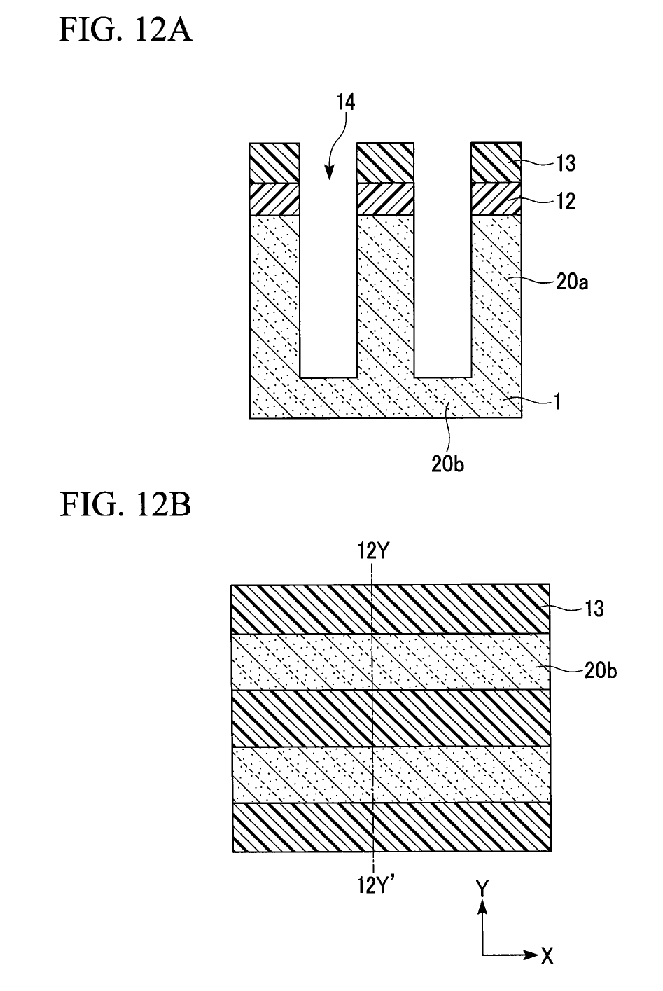

First, as illustrated in FIGS. 12A and 12B, a fin-shaped convex portion 20a is formed. At first, a semiconductor substrate 1 made of a P-type conductive silicon (Si) is prepared. Then, a second mask nitride film 12 made of a silicon nitride (Si₃N₄) film, for example, with a thickness of 50 nm is formed to cover the semiconductor substrate 1.

Then, a second photoresist mask 13 is formed on the second mask nitride film 12. The second photoresist mask 13, as illustrated in FIG. 12B, for example, extends in the X-axis direction and forms a band-shaped repeated pattern with a width of 50 nm and a spacing of 50 nm in Y-axis direction.

Then, the second mask nitride film 12 and the semiconductor substrate 1 are sequentially etched using the second photoresist mask 13 as a mask. At this time, the second mask nitride film 12 protects the upper surface of the convex portion 20a and performs as a hard mask during patterning of the convex portion 20a. Also, in this case, the semiconductor substrate 1 is etched to a depth of about 200 nm. Accordingly, a plurality of convex portions 20a extending in the X-axis direction and a second groove 14 having a depth of about 250 nm are formed.

### (Process of Forming a Bit Line 33 and a Third Impurity Diffusion Layer 27)

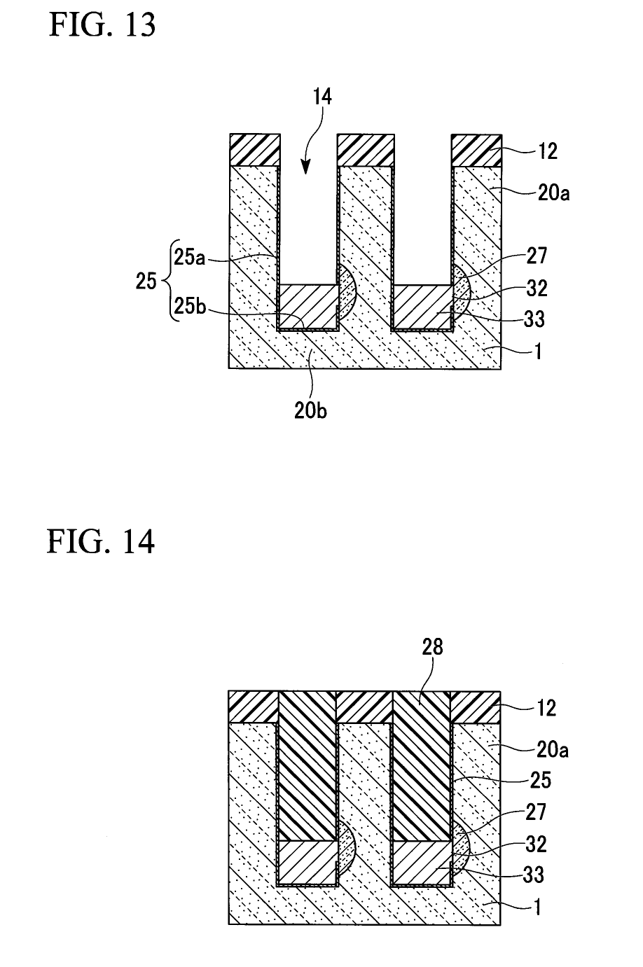

Then, as illustrated in FIG. 13, a bit line 33 and a third impurity diffusion layer 27 are formed. First, the second photoresist mask 13 on the convex portion 20a is removed. Then, the first insulating film 25 is formed to cover the inner wall surfaces and the bottom surface of the second groove 14. Among them, the portion formed on the side surfaces of the second groove 14 is considered as the first insulating film 25a, and the portion formed on the bottom surface of the second groove 14 is considered as the first insulating film 25b.

Then, a portion of the second semiconductor pillar 20 is exposed by removing the first insulating film 25a so that the lower layer portion on one surface side of the first insulation film 25a (the neighborhood of the bottom surface), for example, a portion having a height of about 70 nm from the bottom portion of the second groove 14, extends in the Y-axis direction. Accordingly, an opening portion (which is described as the bit-line contact 32) is formed on the lower layer portion (the neighborhood of the bottom portion) on one surface side of the first insulating film 25.

Then, in the second groove 14, the bit line 33 composed of a conductor is embedded up to a height at which it covers at least a portion of the opening portion (bit-line contact 32). Accordingly, the bit line 33 is configured to be in direct contact with the second semiconductor pillar 20 through the bit-line contact 32. Also, arsenic is diffused onto a portion that is in contact with the bit line 33 of the convex portion 20a. Accordingly, the N-type third impurity diffusion layer 27 is formed as a construction included in the lower layer portion of the convex portion 20a. At this time, phosphorous may be used as an N-type impurity in forming the third impurity diffusion layer 27. Accordingly, the third impurity diffusion layer 27 performs as one side of the source/drain electrodes of the vertical MOS transistor constituting the memory cell.

The method of forming the bit line 33, the bit-line contact 32, and the third impurity diffusion layer 27 is not limited to the method as described above, and for example, they may be formed using a method as disclosed in Japanese Unexamined Patent Application Publication No. 2009-10366.

### (Process of Forming an Embedded Insulating Film 28)

Then, as illustrated in FIG. 14, an embedded insulating film 28 is formed. First, the embedded insulating film 28 made of a silicon oxide film is formed to cover the second mask nitride film 12 and to be embedded in the second groove 14.

At this time, the material of the embedded insulating film 28 is not limited to the silicon oxide film or the like, and a SOD film may be used. In this case, a liner film (not illustrated) composed of a silicon oxynitride film is formed to cover the inner wall portion of the second groove 14. Then a SOD film is coated to cover the liner film and to fill in the second groove 14. Thereafter, by performing heat treatment at high-temperature vapor atmosphere, the film density of the SOD film is increased, and thus the embedded insulating film 28 composed of the liner film and the SOD film is formed.

In this embodiment of the present invention, unlike the first groove 4 in the first embodiment of the present invention, no gate electrode is formed in the second groove 14. Accordingly, the width of the inside of the second groove 14 is larger than the width of the first groove 4 in the first embodiment of the present invention. Thus, according to the design rule to be applied, it becomes possible to accumulate the insulating film without the cavity occurrence even using the typical CVD method. Accordingly, it is sufficient if a means for forming the embedded insulating film 28 is selected in consideration of the design rule to be applied.

Thereafter, the upper surface of the silicon nitride film (embedded insulating film 28) is removed by grinding using the CMP method until the upper surface of the second mask nitride film 12 is exposed.

### (Process of Forming a Third Photoresist Mask 23)

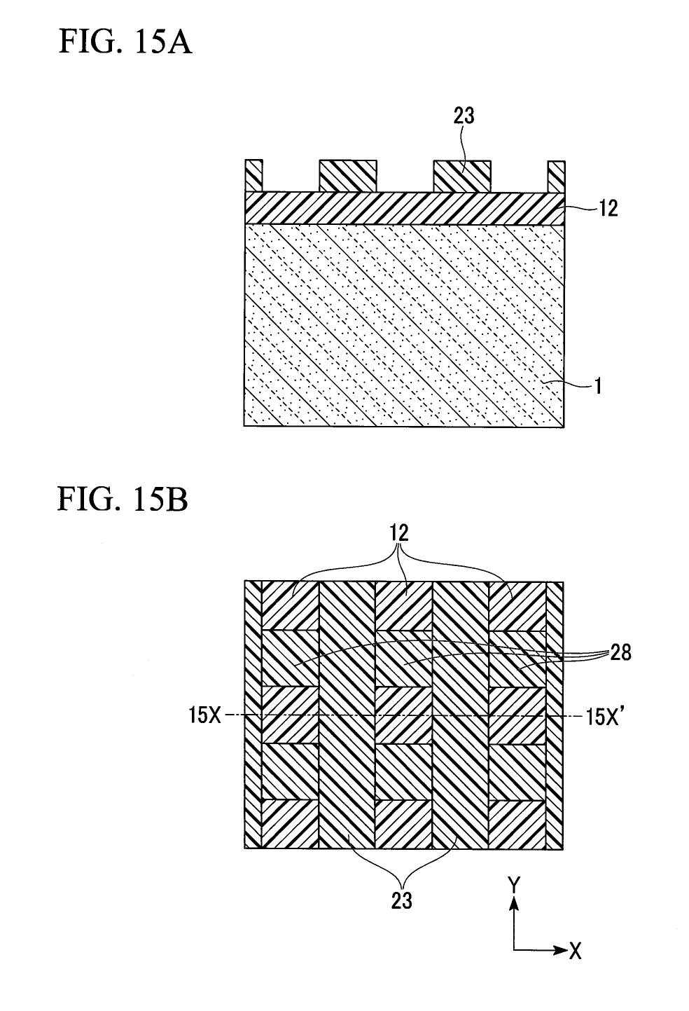

Then, as illustrated in FIGS. 15A and 15B, a third photoresist mask 23 is formed. The third photoresist mask 23, as illustrated in FIG. 15B, for example, extends in the Y-axis direction, and forms a band-shaped repeated pattern with a width of 50 nm and a spacing of 50 nm in X-axis direction.

### (Process of Forming a Second Semiconductor Pillar 20)

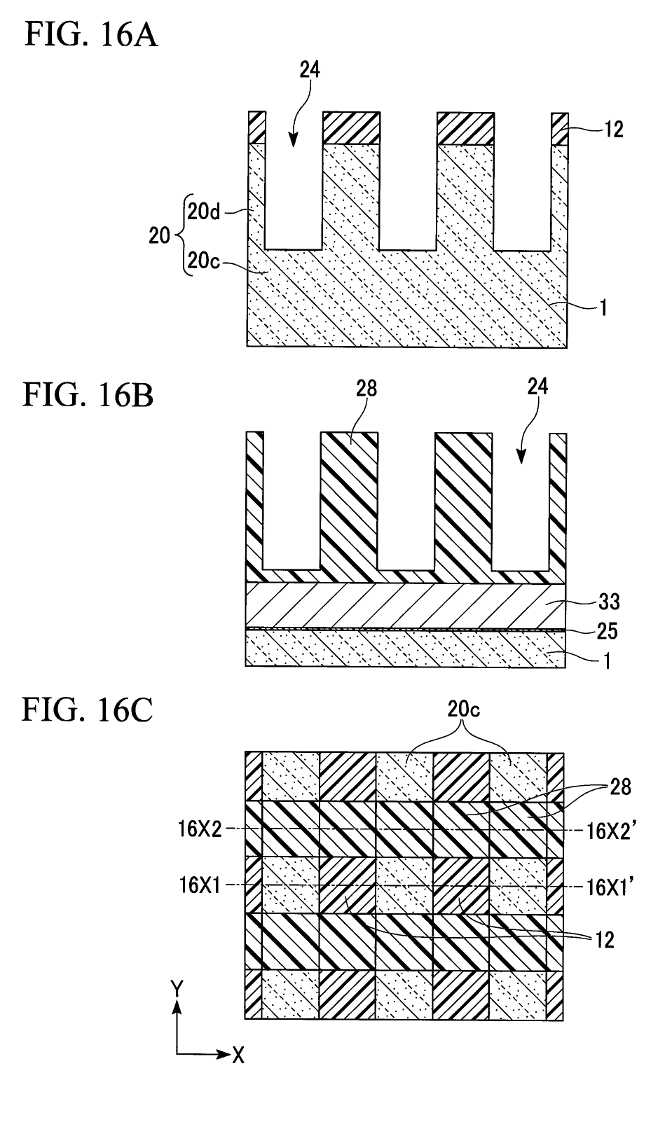

Then, as illustrated in FIG. 16A, a second semiconductor pillar 20 is formed.

First, using the third photoresist mask 23 as a mask, the second mask nitride film 12, the semiconductor substrate 1 (base 20c), and the embedded insulating film 28 are etched. Here, as illustrated in FIG. 16B, the semiconductor substrate 1 and the embedded insulating film 28 are etched, for example, up to the depth of about 150 nm so that the upper surface of the bit line 33 is not exposed. The second mask nitride film 12 protects the upper surface of the pillar portion 20d and performs as a hard mask during patterning the pillar portion 20d. Accordingly, on the bit line 33, the embedded insulating film 28 remains, for example, with a thickness of 30 nm.

Accordingly, as illustrated in FIG. 16C, a third groove 24 with a depth of about 15 nm, which extends in the Y-axis direction and forms a band-shaped repeated pattern with a width of 50 nm and a spacing of 50 nm, is formed. Accordingly, a base 20c composed of the lower layer portion of the convex portion 20a is formed. Also, in an area where the convex portion 20a and the third photoresist mask 23 cross each other, a plurality of pillar portions 20d is formed. These pillar portions 20d are in the form of a tetragon in plan view, and have a width of about 50 nm in the X-axis direction and in the Y-axis direction. Accordingly, the second semiconductor pillar 20 composed of the base 20c and the pillar portions 20d is formed.

### <Second Process> (Process of Forming a Second Gate Electrode Layer 16)

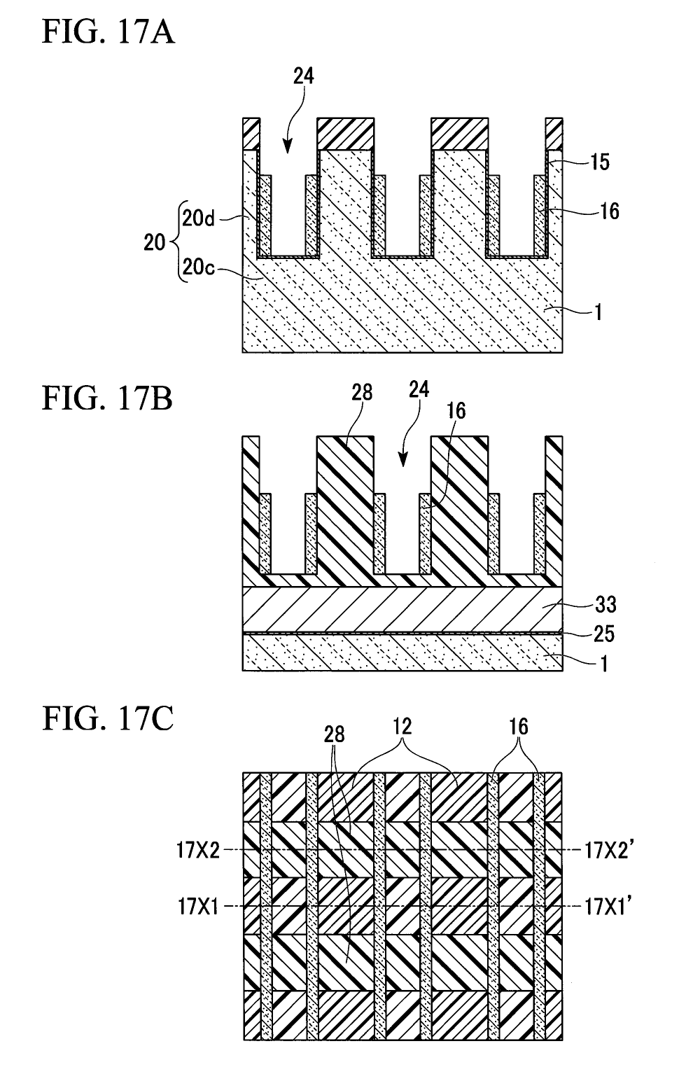

Then, as illustrated in FIGS. 17A to 17C, a second gate electrode 16 is formed.

First, the second gate insulating film 15 is formed to cover side surfaces and bottom surfaces of inner walls of the third groove 24. Then, a material of the second gate electrode 16 (not illustrated), for example, made of a doped silicon film, is formed with a thickness of the film on which the inside of the third groove 24 is not filled to cover the side surfaces of the inner walls of the third groove 24 and the second mask nitride film 12.

At this time, the material of the second gate electrode 16 is not limited to the phosphorous doped silicon film, and may be a high melting point film or a laminated film of the doped silicon film and the high melting point film. Since the second gate electrode 16 is used as a word line of a memory cell, it is preferable to use a material having low resistance.

Then, the material of the second gate electrode 16 on the bottom portion of the third groove 24 and the second mask nitride film 12 is removed by etching back the material of the second gate electrode 16 on the bottom portion of the third groove 24 and the second mask nitride film 12. Accordingly, the second gate electrode 16 is formed, which is separated by the second gate insulating film 15 from the pillar portion 20d and extends in the second direction (Y-axis direction).

At this time, as illustrated in FIG. 17A, a portion of the second gate insulting film 15 is exposed by forming the second gate electrode 16 so that the upper portion of the second gate electrode 16 is lower than the upper portion of the second semiconductor pillar 20. Here, for example, the second gate electrode 16 is formed at a height of about 110 nm from the bottom portion of the third groove 24.

Accordingly, the second gate electrode 16 is formed to cover the second semiconductor pillar 20 and the side walls of the embedded insulating film 28 (side surfaces of inner walls of the third groove 24) and to extend in the second direction (Y-axis direction). Since the second gate electrode 16 is formed as an interconnect film, it performs as a word line of a memory cell.

### <Third Process> (Process of Forming a Second Liner Film 18)

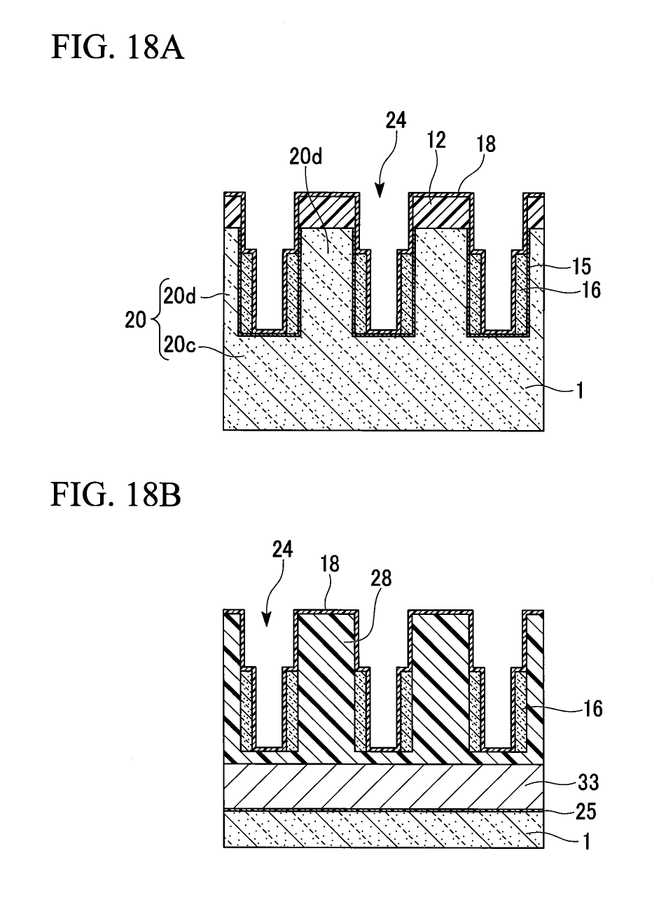

Then, as illustrated in FIGS. 18A and 18B, a second liner film 18 is formed.

First, the second liner film 18 made of a silicon oxynitride film (SiON film) 16, for example, with a thickness of 8 nm is formed to cover the inner wall surfaces of the third groove 24 and the second mask nitride film 12. Since the following process is the same as the process of forming the first liner film 8 according to the first embodiment of the present invention, the explanation thereof will be omitted. Accordingly, the second gate electrode 16 and the second mask nitride film 12 are covered by the second liner film 18.

### (Process of Forming a Third Interlayer Insulating Film 29)

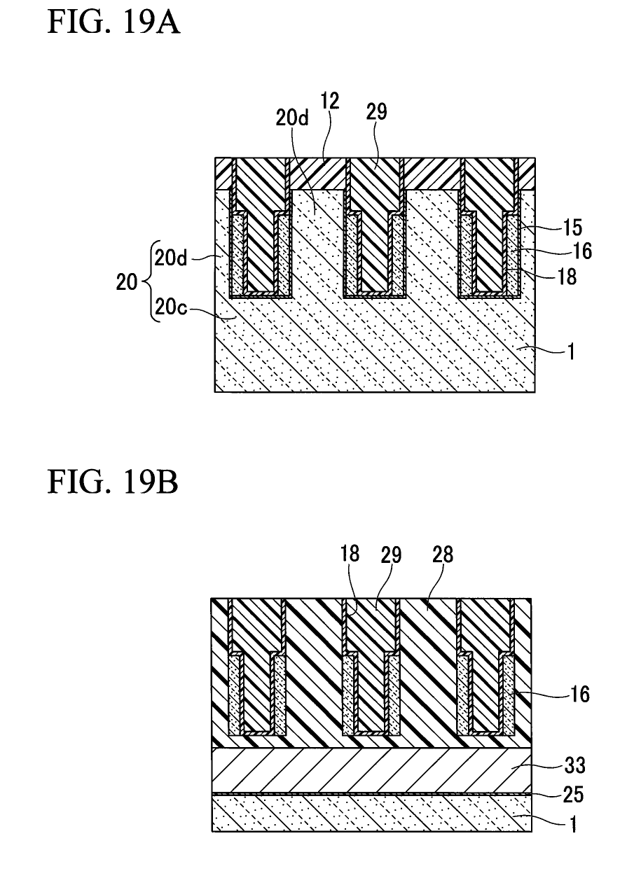

Then, as illustrated in FIGS. 19A and 19B, a third interlayer insulating film 29 is formed.

First, a third interlayer insulating film (SOD film) 29 made of polysilazane is formed (coated) to cover the second liner film 18 and to fill in the third groove 24. Thereafter, the film density of the third interlayer insulating film 29 is increased by performing heat treatment to the third interlayer insulating film 29. This process is the same as the process of forming the first interlayer insulating film 9 according to the first embodiment of the present invention.

### <Fourth Process> (Process of Removing a Second Mask Nitride Film 12)

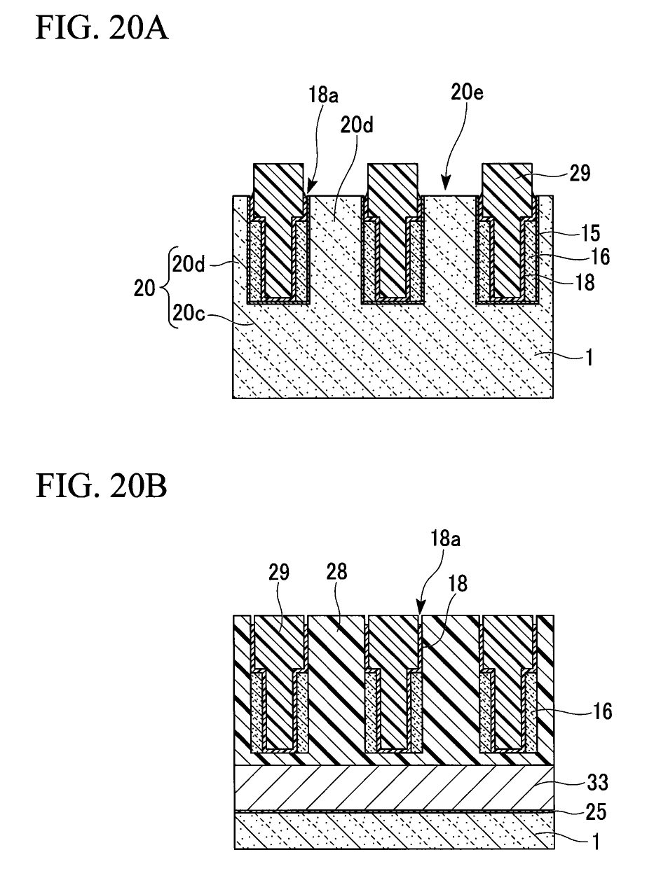

Then, as illustrated in FIGS. 20A and 20B, the second mask nitride film 12 is selectively removed by wet etching using a hot phosphoric acid solution (H₃PO₄). Accordingly, as illustrated in FIG. 20A, a second semiconductor pillar opening portion 20e is formed on a portion from which the second mask nitride film is removed.

During the wet etching, as illustrated in FIG. 20B, the upper portion 18a of the second liner film between the second gate insulating film 15 and the third interlayer insulating film 29 and the upper portion 18a of the second liner film between the embedded insulating film 28 and the third interlayer insulating film 29 are also etched. However, in the same manner as the process of removing the first mask nitride film 2 according to the first embodiment of the present invention, the amount of recess can be suppressed to about 10 nm even if the nitride film is etched to the extent that can remove 100 nm of the nitride film.

Accordingly, the upper portion 18a of the second liner film on the side of the second gate insulating film 15 is more greatly recessed than the upper portion 18a of the second liner film on the side of the third interlayer insulating film 29. Also, as the second liner film 18 becomes thinner, the difference in the amount of recess becomes smaller.

In the case where the embedded insulating film 28 is composed of a liner film (not illustrated) and a SOD film, the liner film below the embedded insulating film 28 is also recessed, but the amount of recess in this case can also be suppressed. Through the above-described process, the second liner film 18 remains on the upper surface of the second gate electrode 16. Accordingly, the second gate electrode 16 is prevented from being exposed.

### (Process of Forming a Fourth Impurity Diffusion Layer 37)

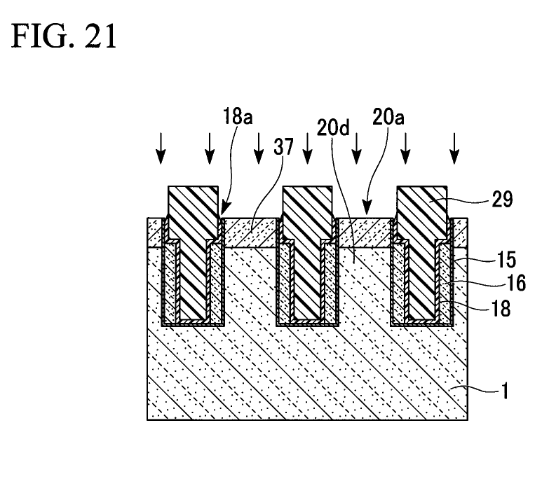

Then, as illustrated in FIG. 21, a fourth impurity diffusion layer 37 is formed. Since this process uses the same method as in the process of forming the second impurity diffusion layer 17 according to the first embodiment of the present invention, the explanation thereof will be omitted. The fourth impurity diffusion layer 37 performs as the other side of the source/drain electrodes of the vertical MOS transistor.

### (Process of Forming a Third Contact Plug 31)

Then, as illustrated in FIGS. 22A to 22D, a third contact plug 31 is formed. Since this process uses the same method as in the process of forming the first contact plug 11 according to the first embodiment, the explanation thereof will be omitted.

### (Process of Forming a Capacitor Element 44)

Then, as illustrated in FIGS. 23A and 23B, a capacitor element 44 is formed.

For example, the first capacitor electrode (lower electrode) 40, which is made of a metal film such as titanium nitride and has an upper portion that is in an open hollow tube shape, is formed to connect on the third contact plug 31. Then, a capacitance insulating film 41 is formed to cover the outer and inner walls and the bottom surface of the first capacitor electrode 40. A material of the capacitance insulating film 41 may use a high dielectric film of zirconium oxide (ZrO₂), hafnium oxide (HfO₂), aluminum oxide (Al₂O₃), and the like, or their laminated film.

Thereafter, for example, a second capacitor electrode (upper electrode) 42 made of a metal film such as titanium nitride, is formed to cover the first capacitor electrode 40 and the capacitance insulating film 41. Accordingly, a capacitor element 44, in which the first capacitor electrode 40 and the second capacitor electrode 42 are separated by the capacitance insulating film 41 from each other, is formed.

Thereafter, a fourth interlayer insulating film 39 is formed to cover the second capacitor electrode 42. Also, a contact plug (not illustrated), which penetrates the respective interlayer insulating films and is in contact with the second gate electrode 16 and the bit line 33, is formed. Also, a metal interconnect 22 that is in contact with the contact plug is formed on the fourth interlayer insulating film 39, and then a protection film 43 is formed to cover the metal interconnect 22. Through the above-described processes, the forming of a memory cell of a DRAM device is completed.

The construction of the bit line 33 or the capacitor element 44 described in this embodiment of the present invention is exemplary, and can be modified without departing from the scope and spirit of the present invention.

Also, the present invention is applicable even in the case where instead of the capacitor element 44, a memory cell composed of a storage element of which the resistance value can be varied by an input of an electric signal and a vertical MOS transistor is used. Specifically, examples of such a memory cell include a phase change memory element (PRAM) and a resistance change memory element (ReRAM).

The application of the present invention is not limited to the case where memory cells are formed, and the present invention is also applicable in the case where the semiconductor device 50 is composed of high-density vertical MOS transistors.

In this embodiment of the present invention, by forming the second liner film 18 using a silicon oxynitride film (SiON film), the removal of the second liner film 18 can be suppressed when the second mask nitride film 12 is etched and over-etched. Accordingly, on the upper surface of the second gate electrode 16, the second liner film 18 remains, and thus the upper surface of the second gate electrode 16 is prevented from being exposed. Accordingly, a short circuit of the third contact plug 31 that is in contact with the second gate electrode 16 and the pillar portion 20d is prevented, and it becomes possible to arrange the vertical MOS transistors in a memory cell area at high density.

Also, since the second liner film 18 can sufficiently remains in the distance ranging from the upper surface of the second gate electrode 16 to the upper surface of the second liner film 18 in comparison to the method in the related art, the insulation of the second gate electrode 16 can be sufficiently secured.

Also, since the removal of the second liner film 18 is suppressed, during the etching of the second mask nitride film 12, it becomes possible to lengthen the etching time until the upper surface of the second gate electrode 16 is exposed in comparison to the method in the related art. By this, the second mask nitride film 12 on the upper surface of the pillar portion 12 is completely removed, and thus the etching remainder of the second mask nitride film 12 can be prevented.

Also, in this embodiment of the present invention, the third contact plug 31 is formed by making the phosphorous doped silicon film (third contact plug) 31 fill a gap between the upper surfaces of the second semiconductor pillars 20 (pillar portion 20d). Due to this, the manufacturing difference in contact area between the second semiconductor pillar 20 (pillar portion 20d) and the third contact plug 31 can be reduced. Accordingly, it becomes possible to suppress the difference in contact resistance.

Also, an opening portion (bit-line contact 32) is provided on the first insulating film 25, and through this bit-line contact 32, the second semiconductor pillar 20 (base 20c) and the bit line 33 are in direct contact with each other. Due to this, the bit line 33 is insulation-separated from the semiconductor substrate 1 and is in contact with the third impurity diffusion layer 27. Accordingly, it becomes possible to heighten the integration of the semiconductor device 50.

### EXAMPLE 1

Hereinafter, the present invention will be described in detail based on examples. However, the present invention is not limited to the examples.

A method of manufacturing a semiconductor device 50 according to Example 1 will be described.

First, a semiconductor substrate 1 made of a P-type conductive silicon (Si) was prepared, and a first mask nitride film 2 made of a silicon nitride (Si₃N₄) film with a thickness of 50 nm was formed to cover the semiconductor substrate 1 by the LP-CVD method. At that time, dichlorosilane (SiH₂Cl₂) and ammonia (NH₃) were used as source gases, and reaction was performed at a high temperature of about 600° C. and under reduced pressure. This state is illustrated in FIG. 1.

Then, a first photoresist mask 3 was formed on the first mask nitride film 2. The first photoresist mask 3, as illustrated in FIG. 2B, was in the form of a tetragon in plan view, for example, with a width of about 100 nm in both an X-axis direction and a Y-axis direction. Also, the first photoresist mask 3 was formed to have patterns which standed in a row at the same interval of about 100 nm in the first direction (X-axis direction).

Then, as illustrated in FIG. 2A, using the first photoresist mask 3 as a mask, the first mask nitride film 2 and the semiconductor substrate 1 were sequentially etched. In this case, the semiconductor substrate 1 was etched up to the depth of about h1=200 nm. Accordingly, first semiconductor pillars 10, each of which is in the form of a tetragon in plan view with a width of about 100 nm in both an X-axis direction and a Y-axis direction, were formed to stand in a row at the same interval of about 100 nm in the first direction (X-axis direction). Also, a first groove 4 was formed to surround the circumference of the first semiconductor pillar 10.

Then, the first photoresist mask 3 was removed and the first gate insulation film 5 made of a silicon dioxide film (SiO₂) was formed by thermal oxidation method with a thickness of 5 nm to cover the side surfaces of the inner walls and the bottom surface of the first groove 4.

Then, the first gate electrode layer 6a made of a polysilicon film (phosphorous doped silicon film) that contains phosphorous as the impurity was formed with a thickness of 30 nm to cover the inner wall surfaces of the first groove 4 and the first mask nitride film 2. Accordingly, as illustrated in FIG. 3, the first gate electrode layer 6a was formed.

Then, by performing an anisotropic dry etching, the first gate electrode layer 6a was etched back on the bottom portion of the first groove 4 and the first mask nitride film 2. Accordingly, the first gate electrode 6 having a surround gate structure that completely surrounds the outer periphery of the first semiconductor pillar 10 was formed.

In this case, the height h2 of the first gate electrode 6, for example, was set to 150 nm, which is lower than the height of the first semiconductor pillar 10. Also, the height h3 of a portion, on which the first gate insulating film 5 was exposed, of the side surface of the upper portion of the first semiconductor pillar 10 was set to 50 nm. This state is illustrated in FIGS. 4A and 4B.

Then, as illustrated in FIG. 5, an impurity injection was performed onto the semiconductor substrate 1 that was positioned below the bottom portion of the first groove 4 via the first gate insulating film 5. In this case, the impurity introduction was performed by injecting arsenic with energy of 20 Kev and doze of 1×10¹⁵ atoms/cm² using an ion injection method. Accordingly, the first impurity diffusion layer 7 was formed below the first gate insulting film 5 of the lower layer portion of the first semiconductor pillar 10.

Then, as illustrated in FIG. 6, a first liner film 8 composed of a silicon oxynitride (SiON) film was formed with a thickness of 10 nm to cover the inner walls of the first groove 4 and the first mask nitride film 2. At that time, the forming of the first liner film 8 was performed using the LP-CVD method and by reacting dichlorosilane (SiH₂Cl₂), nitrous oxide (N₂O), and ammonia (NH₃) as source gases at a high temperature of about 600° C. and under reduced pressure.

Then, as illustrated in FIG. 7, a first interlayer insulating film (SOD film) 9 made of polysilazane was coated to cover the first liner film 8 and to fill in the first groove 4.

Then, by performing annealing process for 60 minutes under oxidation atmosphere including vapor (H₂O) at a high temperature of 700° C., the film density of the first interlayer insulating film (SOD film) 9 was increased. Thereafter, the upper surface of the first mask nitride film 2 was exposed by removing the surface of the first interlayer insulating film (SOD film) 9 and the first liner film 8 on the first mask nitride film 2 through grinding using a CMP method.

Then, as illustrated in FIG. 8A, the whole upper surface of the first semiconductor pillar 10 was exposed by selectively removing the first mask nitride film 2 by wet etching using a hot phosphoric acid solution (H₃PO₄).

During the wet etching, the etching speed of the hot phosphoric acid solution (H₃PO₄) was about 5 nm/minute with respect to the silicon nitride film. The etching was performed for about 20 minutes to the extent that can remove 100 nm of the nitride film. That is, over-etching to the extent that can further etch 50 nm of the nitride film was added after the first mask nitride film 2 having a thickness of 50 nm was removed.

In this embodiment of the present invention, as a result of evaluating the etching speed of the SiON film by the hot phosphoric acid solution, the etching speed of the SiON film formed according to this embodiment of the present invention was 1 nm/minute, which was about ⅕ of the etching speed of the silicon nitride film. By performing 100% of over-etching with respect to the first mask nitride film 2 on the above-described condition, the upper surface of the first liner film (SiON film) 8 (the upper portion 8a of the first liner film) was recessed as far as about 10 nm from the upper surface of silicon of the first semiconductor pillar 10.

FIG. 8B is an enlarged view of a portion ranging from the first semiconductor pillar opening portion 10a to the first gate electrode 6. In this embodiment of the present invention, as a result of performing the etching and over-etching of up to the extent that can remove 100 nm of the first mask nitride film 2 with respect to the first mask nitride film 2 having a thickness of 50 nm, the upper portion 8a of the first liner film was recessed for a distance of about h5=10 nm from the upper surface of the first semiconductor pillar 10. Accordingly, the first liner film 8 remained for about h4=40 nm from the upper surface of the first gate electrode 6.

After the wet etching is performed, the first liner film (SiON film) 8 was shaped so that the upper portion 8a of the first liner film on the side of the first semiconductor pillar 10 was more greatly recessed than the upper portion 8a of the first liner film on the side of the first interlayer insulating film 9.

Then, arsenic was introduced onto the upper surface of the first semiconductor pillar 10 by ion injection on a condition of energy of 10 Kev and doze of 1×10¹⁵ atoms/cm². Accordingly, as illustrated in FIG. 9, the second impurity film 17 was formed on the upper layer portion of the first semiconductor pillar 10.

Then, a phosphorous doped silicon film (first contact plug 11) was formed to cover the first semiconductor pillar 10 and to fill in the first semiconductor pillar opening portion 10a.

Then, the upper surface of the first interlayer insulating film 9 was exposed by removing the upper surface of the phosphorous doped silicon film (first contact plug 11) through grinding using a CMP method. Accordingly, the first contact plug 11 was formed as illustrated in FIG. 10.

Then, a second interlayer insulating film 19 made of a silicon oxide film was formed to cover the first interlayer insulating film 9 and the first contact plug 11. Then, by performing annealing through lamp heating, the first impurity diffusion layer 7 and the second impurity diffusion layer 17 were activated. At this time, the annealing condition was under a nitrogen (N₂) atmosphere, at 900° C. for 30 seconds. Accordingly, the first impurity diffusion layer 7 was diffused up to the portion of the semiconductor substrate 1 below the first gate electrode 6, and the second impurity diffusion layer 17 was diffused up to the position beside the first gate electrode 6.

Then, using the known method, the second contact plug 21 was formed, which was in contact with the upper surface of the first contact plug 11 and penetrated the second interlayer insulating film 19. Then, a contact plug (not illustrated) was formed, which was in contact with the first gate electrode 6 and the first impurity diffusion layer 7.

Then, a metal interconnect 22 was formed on the second contact plug 21. Thereafter, by further forming an interconnect film (not illustrated) on the upper layer and a protection film on the surface, the semiconductor device 50 provided with the vertical MOS transistors as illustrated in FIG. 11 was completed.

### EXAMPLE 2

A method of manufacturing a semiconductor device 50 according to Example 2 will be described.

First, a second mask nitride film 12 made of a silicon nitride (Si₃N₄) film with a thickness of 50 nm was formed to cover a semiconductor substrate 1 made of a P-type conductive silicon (Si).

Then, on the second mask nitride film 12, as illustrated in FIG. 12B, a second photoresist mask 13 was formed to extend in the first direction (X-axis direction) and to form a band-shaped repeated pattern with a width of 50 nm and a spacing of 50 nm in the second direction (Y-axis direction).

Then, the second mask nitride film 12 and the semiconductor substrate 1 were sequentially etched using the second photoresist mask 13 as a mask. At that time, the semiconductor substrate 1 was etched to a depth of 200 nm. Accordingly, as illustrated in FIGS. 12A and 12B, a plurality of convex portions 20a extending in the first direction (X-axis direction) and a second groove 14 having a depth of 250 nm were formed.

Then, the second photoresist mask 13 on the convex portion 20a was removed, and then the first insulating film 25 was formed to cover the inner wall surfaces and the bottom surface of the second groove 14.

Then, a portion of the second semiconductor pillar 20 was exposed by removing a portion having a height of about 70 nm from the bottom portion of the second groove 14 so that the portion extended in the Y-axis direction. Accordingly, an opening portion (which is described as the bit-line contact 32) was formed on the lower layer portion on one surface side of the first insulating film 25.

Then, in the second groove 14, the bit line 33 composed of a conductor was embedded up to a height at which it covers at least a portion of the opening portion (bit-line contact 32). Accordingly, the N-type third impurity diffusion layer 27 was formed as a construction included in the lower layer portion of the convex portion 20a.

Then, an embedded insulating film 28 made of a silicon oxide film was formed to cover the second mask nitride film 12 and to fill in the second groove 14.

Thereafter, the upper surface of the silicon nitride film (embedded insulating film 28) was removed by grinding using the CMP method until the upper surface of the second mask nitride film 12 is exposed. Accordingly, as illustrated in FIG. 14B, the embedded insulating film was formed.

Then, as illustrated in FIGS. 15A and 15B, a third photoresist mask 23 was formed to extend in the Y-axis direction and to form a band-shaped repeated pattern with a width of 50 nm and a spacing of 50 nm in X-axis direction.

Then, using the third photoresist mask 23 as a mask, the second mask nitride film 12, the semiconductor substrate 1 (base 20c), and the embedded insulating film 28 were etched to a depth of about 150 nm. Accordingly, on the bit line 33, the embedded insulating film 28 remains with a thickness of 30 nm.

Accordingly, as illustrated in FIG. 16C, a third groove 24 with a depth of about 150 nm, which extended in the Y-axis direction and formed a band-shaped repeated pattern with a width of 50 nm and a spacing of 50 nm, was formed. Accordingly, a base 20c composed of the lower layer portion of the convex portion 20a was formed. Also, in an area where the convex portion 20a and the third photoresist mask 23 crossed each other, a plurality of pillar portions 20d, which was in the form of a tetragon in plan view, and had a width of 50 nm in the X-axis direction and in the Y-axis direction, was formed. Accordingly, the second semiconductor pillar 20 composed of the base 20c and the pillar portions 20d was formed.

Then, the second gate insulating film 15 was formed to cover side surfaces and bottom surfaces of inner walls of the third groove 24. Then, a material of the second gate electrode 16 (not illustrated) made of a doped silicon film was formed to cover the side surfaces and bottom surfaces of the inner walls of the third groove 24 and the second mask nitride film 12.

Then, the material of the second gate electrode 16 on the bottom portion of the third groove 24 and the second mask nitride film 12 was removed by etch back. Accordingly, the second gate electrode 16, which was separated by the second gate insulating film 15 from the pillar portion 20d and extended in the second direction (Y-axis direction), was formed.

At this time, as illustrated in FIG. 17A, the upper portion of the second gate electrode 16, having a height of about 110 nm from the bottom portion of the third groove 24, was formed to be lower than the upper portion of the second semiconductor pillar 20. Accordingly, a portion of the second gate insulting film 15 was exposed.

Accordingly, the second gate electrode 16 was formed to cover the second semiconductor pillar 20 and the side walls of the embedded insulating film 28 (side surfaces of inner walls of the third groove 24) and to extend in the second direction (Y-axis direction). This state is illustrated in FIGS. 17A to 17C.

Then, a second liner film 18 made of a silicon oxynitride film (SiON) with a thickness of 8 nm was formed to cover the inner wall surfaces of the third groove 24 and the second mask nitride film 12. Accordingly, as illustrated in FIGS. 18A and 18B, the second gate electrode 16 and the second mask nitride film 12 were covered by the second liner film 18.

Then, a third interlayer insulating film (SOD film) 29 made of polysilazane was formed to cover the second liner film 18 and to fill in the third groove 24. Thereafter, the film density of the third interlayer insulating film 29 was increased by performing heat treatment to the third interlayer insulating film 29. This state is illustrated in FIGS. 19A and 19B.

Then, the nitride film was etched so far as 100 nm that could be removable by wet etching using a hot phosphoric acid solution (H₃PO₄). Accordingly, the second mask nitride film 12 was selectively removed, and a second semiconductor pillar opening portion 20e was formed.

By the wet etching, the upper portion 18a of the second liner film between the second gate insulating film 15 and the third interlayer insulating film 29, and the upper portion 18a of the second liner film between the embedded insulating film 28 and the third interlayer insulating film 29 were recessed for about 10 nm.

Accordingly, the upper portion 18a of the second liner film on the side of the second gate insulating film 15 was more greatly recessed than the upper portion 18a of the second liner film on the side of the third interlayer insulating film 29. Also, the second liner film 18 remained on the upper surface of the second gate electrode 16. this state is illustrated in FIGS. 20A and 20B.

Then, as illustrated in FIG. 21, a fourth impurity diffusion layer 37 was formed and then as illustrated in FIGS. 22A to 22D, the third contact plug 31 was formed.

Then, a first capacitor electrode (lower electrode) 40, a capacitance insulating film 41, and a second capacitor electrode (upper electrode) 42 were sequentially formed. Accordingly, as illustrated in FIGS. 23A and 23B, a capacitor element 44 was formed, in which the first capacitor electrode 40 and the second capacitor electrode 42 were separated by the capacitance insulating film 41 from each other.

Thereafter, a fourth interlayer insulating film 39, a contact plug (not illustrated), a metal interconnect 22, and a protection film 43 were sequentially formed to form a memory cell of a DRAM device.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention. A liner film, which acts as a diffusion barrier and adhesion promoter,

What is claimed is:

1. A method of forming a semiconductor device, the method comprising:
forming a first semiconductor structure which extends upwardly in a direction perpendicular to a main surface of a semiconductor substrate;
forming a first insulating film which extends on a surface of the first semiconductor structure;
forming a gate electrode which extends on the first insulating film, the gate electrode having a top surface which is lower than a top surface of the first semiconductor structure; and
forming a liner film which comprises first and second liner portions, the first liner portion covering the gate electrode, the second liner portion extending upwardly from the top surface of the gate electrode,
wherein the liner film includes nitrogen and oxygen.

2. The method according to claim 1, further comprising:
forming a contact plug over the first semiconductor structure and the second liner portion, while the second liner portion being present over the gate electrode and separating the first semiconductor structure from the contact plug.

3. The method according to claim 2, further comprising:
forming a first inter-layer insulating film which covers the liner film before forming the contact plug.

4. The method according to claim 3, further comprising:
performing a heat treatment in an oxidation atmosphere, after forming the first inter-layer insulating film and before forming the contact plug.

5. The method according to claim 4, further comprising:
forming a first mask pattern over the semiconductor substrate,
wherein forming the first semiconductor structure comprises selectively removing the semiconductor substrate using the first mask pattern,
the first mask pattern is removed after performing the heat treatment and before forming the contact plug over the first semiconductor structure.

6. The method according to claim 5, further comprising:
forming a first diffusion region in an upper portion of the first semiconductor structure after removing the first mask pattern and before forming the contact plug on the first diffusion region.

7. The method according to claim 6, wherein forming the first semiconductor structure comprises:
forming at least two of grooves on the main surface of the semiconductor substrate to form a semiconductor fin structure; and
removing a part of the fin structure to form a pillar structure of the semiconductor substrate.

8. The method according to claim 7, wherein forming the first inter-layer insulating film comprises filling the grooves with the first inter-layer insulating film.

9. The method according to claim 6, further comprising:
forming a second diffusion region beneath the surface of the semiconductor substrate,
wherein forming the first semiconductor structure comprises forming a plurality of first semiconductor pillars, each of which is surrounded by first grooves, each of the first groove having a bottom surface beneath which the second diffusion region is formed, and
forming the gate electrode comprises forming a plurality of gate electrodes, each of which surrounds the first semiconductor pillar.

10. The method according to claim 6, wherein forming the first semiconductor structure comprises:
forming a plurality of semiconductor fins, each of which is defined by second grooves, the plurality of semiconductor fins and the second groves extending in a first horizontal direction;
forming bit lines over the surface of the semiconductor substrate after forming the first semiconductor structure, the bit line extending over a bottom surface of the second groove, a part of the bit line contacting directly a part of a side surface of the semiconductor fin;
diffusing an impurity from the bit line into the semiconductor fin to form a third diffusion region in the second fin; and
forming third grooves in the semiconductor substrate, the third grooves extending in a second horizontal direction different from the first horizontal direction, the third grooves separating the semiconductor fins into semiconductor pillars, the third groove having a bottom level which is higher than a center level of the third diffusion region.

11. The method according to claim 10, wherein forming the gate electrode comprises:
forming a plurality of gate electrodes, each of which extends in the second horizontal direction, the gate electrode facing toward the semiconductor pillar through the gate insulating film, and
wherein forming the first inter-layer insulating film comprises forming the first inter-layer insulating film which fills the third grooves after forming the liner film.

12. The method according to claim 11, wherein forming the bit lines comprises:
forming openings in the gate insulating films in the second grooves, the opening extending in the first horizontal direction, the opening exposing the part of the side surface of the semiconductor fin;
filling the second grooves with the bit lines so that the bit lines contact directly the part of the side surface of the semiconductor fin at the opening.

13. The method according to claim 5, wherein the first mask pattern is removed by a wet etching process using a hot phosphoric acid.

14. The method according to claim 3, wherein forming the first inter-layer insulating film comprises forming a polysilazane film.

15. The method according to claim 5, wherein the first mask pattern is removed while the liner film remains.

16. The method according to claim 5, wherein the second liner portion is interposed between the inter-layer insulating film and the gate insulating film, and removing the first mask pattern comprises forming a recess at the top portion of the second liner portion, the recess is closer to the gate insulating film than to the inter-layer insulating film.

17. The method according to claim 1, wherein the liner film is a silicon oxynitride film which contains at least 11 atm % of nitrogen atoms,
wherein the number of oxygen atoms in the silicon oxynitride film is at least two-times as many as the number of nitrogen atoms.

18. The method according to claim 17, wherein the liner film is a silicon oxynitride film which contains 13 atm % to 18 atm % of nitrogen atoms, and
wherein the number of oxygen atoms in the silicon oxynitride film is three-times to five-times as many as the number of nitrogen atoms.

19. A method of forming a semiconductor device, the method comprising:
forming a nitride mask over a semiconductor substrate;
selectively etching the semiconductor substrate to form semiconductor pillars and grooves that define the semiconductor pillars, the semiconductor pillars extending upwardly from the semiconductor substrate;
forming gate insulating films which cover the grooves, while the nitride mask remaining over the pillars;
forming gate electrodes on the gate insulating films, while the nitride mask remaining over the pillars, the gate electrodes being lower in top level than the semiconductor pillars, the gate electrode facing toward the semiconductor pillar through the gate insulating film;
forming liner films of silicon oxynitride which cover the grooves;
forming spin-on-dielectrics-interlayer insulating films which cover the liner films and fill the grooves;
performing a heat treatment of the spin-on-dielectrics-interlayer insulating films in an oxidation atmosphere to increase a film density of the spin-on-dielectrics-interlayer insulating film; and
selectively removing the nitride mask.

20. A method of forming a semiconductor device, the method comprising:
forming semiconductor pillars and grooves using a mask, the pillars being defined by the grooves, the pillars extending upwardly from a surface of a semiconductor substrate;
forming gate electrodes which extend surrounding the semiconductor pillars, the gate electrode being lower in top level than the semiconductor pillar;
forming liner films covering the gate electrodes, the liner film extending upwardly from the top of the gate electrode, the liner film extending along an upper portion of the side surface of the semiconductor pillar, the upper portion of the side surface being positioned over the top of the gate electrode;
forming a first inter-layer insulating film which covers the liner film;
performing a heat treatment in an oxidation atmosphere to increase a film density of the first inter-layer insulating film;
selectively removing the mask; and
forming contact plugs over the semiconductor pillars and the liner films, while the liner films being present over the gate electrodes and separating the semiconductor pillars from the contact plugs.
